(19) United States
(12) Patent Application Publication
(10) Pub. No.: US 2025/0113631 A1
(43) Pub. Date: Apr. 3, 2025

(54) SEMICONDUCTOR DEVICE

(71) Applicant: SONY SEMICONDUCTOR SOLUTIONS CORPORATION, KANAGAWA (JP)

(72) Inventors: MANABU TOMITA, KANAGAWA (JP); YUTA NISHIOKA, KANAGAWA (JP)

(21) Appl. No.: 18/730,274

(22) PCT Filed: Dec. 22, 2022
(86) PCT No.: PCT/JP2022/047287

§ 371 Date: Jul. 18, 2024

(30) Foreign Application Priority Data
Jan. 27, 2022 (JP) 2022-010968

(51) Int. Cl. H10F 39/12; H01L 21/68; H01L 25/18; H10F 39/00

(52) U.S. Cl. CPC H10F 39/198; H01L 21/68; H01L 25/18; H10F 39/809; H10F 39/811

(57) ABSTRACT

Provided is a semiconductor device capable of quickly and accurately detecting positional shift of a first semiconductor structure and a second semiconductor structure while suppressing an increase in size of the first semiconductor structure and/or the second semiconductor structure. A semiconductor device according to the present technology is a semiconductor device having a stacked structure in which a first semiconductor structure and a second semiconductor structures are stacked and bonded, in which the first semiconductor structure includes a first connection terminal exposed to a first bonding surface that is a bonding surface to the second semiconductor structure, the second semiconductor structure includes a second connection terminal exposed to a second bonding surface that is a bonding surface to the first semiconductor structure, and bonded to the first connection terminal, and the stacked structure includes at least one of a first electrode provided in the first semiconductor structure, and capable of changing an electrical characteristic with respect to the second semiconductor structure according to a positional shift between the first connection terminal and the second connection terminal, or a second electrode provided in the second semiconductor structure, and capable of changing an electrical characteristic with respect to the first semiconductor structure according to the positional shift.

### TECHNICAL FIELD

The technology according to the present disclosure (hereinafter also referred to as “the present technology”) relates to a semiconductor device.

### BACKGROUND ART

Conventionally, a semiconductor device in which first and second semiconductor structures are stacked and bonded is known (see, for example, Patent Document 1).

### CITATION LIST

### Patent Document

Patent Document 1: WO 2013/179764 A

### SUMMARY OF THE INVENTION

### Problems to be Solved by the Invention

However, in the conventional semiconductor device, there is room for improvement in quickly and accurately detecting positional shift of the first and second semiconductor structures while suppressing an increase in size of the first semiconductor structure and/or the second semiconductor structure.

Therefore, an object of the present technology is to provide a semiconductor device capable of quickly and accurately detecting positional shift of first and second semiconductor structures while suppressing an increase in size of the first semiconductor structure and/or the second semiconductor structure.

### Solutions to Problems

The present technology is a semiconductor device having a stacked structure in which a first semiconductor structure and a second semiconductor structure are stacked and bonded, in which
the first semiconductor structure includes a first connection terminal exposed to a first bonding surface that is a bonding surface to the second semiconductor structure,
the second semiconductor structure includes a second connection terminal exposed to a second bonding surface that is a bonding surface to the first semiconductor structure, and bonded to the first connection terminal, and
the stacked structure includes at least one of
a first electrode provided in the first semiconductor structure, and capable of changing an electrical characteristic with respect to the second semiconductor structure according to a positional shift between the first connection terminal and the second connection terminal, or
a second electrode provided in the second semiconductor structure, and capable of changing an electrical characteristic with respect to the first semiconductor structure according to the positional shift.

The stacked structure may include the first electrode, and the first electrode may be provided in the first semiconductor structure so as to be exposed to the first bonding surface, and a state of the first electrode may be variable between a state of being in conduction with the second semiconductor structure and a state of being not in conduction with the second semiconductor structure according to the positional shift.

The first electrode may be disposed at a position where a state of the first electrode is changeable between a contact state of being in contact with the second connection terminal and a non-contact state of being not in contact with the second connection terminal according to the positional shift.

The state of the first electrode may be different between the contact state and the non-contact state between when the positional shift is equal to or less than a predetermined value and when the positional shift exceeds the predetermined value.

The first electrode may be in the non-contact state when the positional shift is equal to or less than the predetermined value, and may be in the contact state when the positional shift exceeds the predetermined value.

The first electrode may be in the contact state when the positional shift is equal to or less than the predetermined value, and may be in the non-contact state when the positional shift exceeds the predetermined value.

The stacked structure may include the second electrode, and the second electrode may be provided in the second semiconductor structure so as to be exposed to the second bonding surface, and a state of the second electrode may be variable between a state of being in conduction with the first semiconductor structure and a state of being not in conduction with the first semiconductor structure according to the positional shift.

The second electrode may be disposed at a position where a state of the second electrode is changeable between a contact state of being in contact with the first connection terminal and a non-contact state of being not in contact with the first connection terminal according to the positional shift.

The state of the second electrode may be different between the contact state and the non-contact state between when the positional shift is equal to or less than a predetermined value and when the positional shift exceeds the predetermined value.

The second electrode may be in the non-contact state when the positional shift is equal to or less than the predetermined value, and may be in the contact state when the positional shift exceeds the predetermined value.

The second electrode may be in the contact state when the positional shift is equal to or less than the predetermined value, and may be in the non-contact state when the positional shift exceeds the predetermined value.

The stacked structure may include the first electrode and the second electrode.

The first electrode and the second electrode may be disposed at positions where states of the first electrode and the second electrode are changeable between a contact state of being in contact with each other and a non-contact state of being not in contact with each other according to the positional shift.

The states of the first electrode and the second electrode may be different between the contact state and the non-contact state between when the positional shift is equal to or less than a predetermined value and when the positional shift exceeds the predetermined value.

The first electrode and the second electrode may be in the non-contact state when the positional shift is equal to or less than the predetermined value, and may be in the contact state when the positional shift exceeds the predetermined value.

The first electrode and the second electrode may be in the contact state when the positional shift is equal to or less than the predetermined value, and may be in the non-contact state when the positional shift exceeds the predetermined value.

The stacked structure may include the first electrode and the second electrode, and the first electrode and the second electrode may be arranged at positions where capacitance between the first electrode and the second electrode is changeable according to the positional shift.

The stacked structure may include a detection system that electrically detects a positional relationship between the first electrode and the second electrode to detect a magnitude and/or a direction of the positional shift.

The stacked structure may include a determination system that is provided in at least one of the first semiconductor structure or the second semiconductor structure, and determines a change in the electrical characteristic between the first electrode and the second electrode.

The first semiconductor structure and the second semiconductor structure may have different sizes.

### BRIEF DESCRIPTION OF DRAWINGS

FIG. 1A is an exploded perspective view schematically illustrating a configuration example (wafer unit) of a stacked structure CIS. FIG. 1B is an exploded perspective view and a cross-sectional view schematically illustrating a configuration example (chip unit) of the stacked structure CIS.

FIG. 2 is views for describing a conventional method of bonding WoW.

FIGS. 3A and 3B are views for describing a conventional method of aligning wafers.

FIG. 4 is enlarged views of a conventional alignment mark.

FIG. 5A is views for describing a conventional method of aligning CoC or CoW. FIG. 5B is a view for describing a problem in alignment of a conventional multilayer structure.

FIGS. 6A to 6C are views for describing a problem of interlayer bonding in a conventional multilayer structure. FIG. 6D is a view for describing downsizing of connection terminals.

FIGS. 7A and 7B are views respectively schematically illustrating cross-sectional configurations of configuration examples 1 and 2 of a semiconductor device according to an embodiment of the present technology. FIG. 7C is a view for describing effects of the configuration examples 1 and 2 of the semiconductor device according to the embodiment of the present technology.

FIG. 8 is a view schematically illustrating a cross-sectional configuration of a semiconductor device according to an example 1 of the embodiment of the present technology.

FIGS. 9A to 9D are diagrams schematically illustrating a planar configuration example of the semiconductor device according to the example 1 of the embodiment of the present technology.

FIG. 10 is a cross-sectional view schematically illustrating a state at the time of bonding the first and second semiconductor structures in the semiconductor device according to the embodiment of the present technology.

FIGS. 11A and 11B are views illustrating a configuration example 1 of a positional shift detection system of the semiconductor device according to the embodiment of the present technology.

FIGS. 12A and 12B are views illustrating the configuration example 1 of the positional shift detection system of the semiconductor device according to the embodiment of the present technology.

FIGS. 13A and 13B are views illustrating a configuration example 2 of the positional shift detection system of the semiconductor device according to the embodiment of the present technology.

FIGS. 14A and 14B are views illustrating the configuration example 2 of the positional shift detection system of the semiconductor device according to the embodiment of the present technology.

FIGS. 15A and 15B are views illustrating a configuration example 3 of the positional shift detection system of the semiconductor device according to the embodiment of the present technology.

FIGS. 16A and 16B are views illustrating the configuration example 3 of the positional shift detection system of the semiconductor device according to the embodiment of the present technology.

FIGS. 17A and 17B are views illustrating a configuration example 4 of the positional shift detection system of the semiconductor device according to the embodiment of the present technology.

FIGS. 18A and 18B are views illustrating the configuration example 4 of the positional shift detection system of the semiconductor device according to the embodiment of the present technology.

FIGS. 19A and 19B are views illustrating a configuration example 5 of the positional shift detection system of the semiconductor device according to the embodiment of the present technology.

FIGS. 20A and 20B are views illustrating the configuration example 5 of the positional shift detection system of the semiconductor device according to the embodiment of the present technology.

FIGS. 21A and 22B are views illustrating a configuration example 6 of the positional shift detection system of the semiconductor device according to the embodiment of the present technology.

FIGS. 22A and 22B are views illustrating a configuration example 7 of the positional shift detection system of the semiconductor device according to the embodiment of the present technology.

FIGS. 23A and 23B are views illustrating a configuration example 8 of the positional shift detection system of the semiconductor device according to the embodiment of the present technology.

FIGS. 24A to 24E are views illustrating a configuration example 9 of the positional shift detection system of the semiconductor device according to the embodiment of the present technology.

FIGS. 25A and 25B are views illustrating a configuration example 10 of the positional shift detection system of the semiconductor device according to the embodiment of the present technology.

FIG. 26 is a view illustrating a configuration example 11 of the positional shift detection system of the semiconductor device according to the embodiment of the present technology.

FIGS. 27A and 27B are views illustrating a configuration example 12 of the positional shift detection system of the semiconductor device according to the embodiment of the present technology.

FIGS. 28A and 28B are views illustrating a configuration example 13 of the positional shift detection system of the semiconductor device according to the embodiment of the present technology. FIG. 28C is a diagram illustrating an example using a selection circuit.

FIG. 29 is a diagram illustrating a connection relationship of circuits in the semiconductor device according to the embodiment of the present technology.

FIG. 30 is a diagram for describing a method (conforming to JTAG) for sequentially inspecting a plurality of devices.

FIG. 31 is a diagram for describing a method (conforming to JTAG) of sequentially performing a plurality of inspection contents for each device.

FIG. 32 is a diagram for describing an example in which a positional shift inspection circuit is incorporated in an analog TEST device group.

FIG. 33 is diagrams illustrating a configuration example 1 of a positional shift inspection circuit of the semiconductor device according to the embodiment of the present technology.

FIG. 34 is diagrams illustrating a configuration example 2 of the positional shift inspection circuit of the semiconductor device according to the embodiment of the present technology.

FIG. 35 is tables and diagrams for describing a method of outputting a resistance value from the positional shift inspection circuit of the semiconductor device according to the embodiment of the present technology.

FIG. 36 is a diagram illustrating a system configuration example including peripheral devices used for positional shift detection performed in the semiconductor device according to the embodiment of the present technology.

FIG. 37 is a flowchart for describing an example of a method of bonding first and second semiconductor structures performed at the time of manufacturing the semiconductor device according to the embodiment of the present technology.

FIG. 38 is a flowchart for describing an example of positional shift detection processing of FIG. 37.

FIG. 39 is a cross-sectional configuration view of a semiconductor device according to a modification 1 of the present technology.

FIG. 40 is a cross-sectional configuration view of a semiconductor device according to a modification 2 of the present technology.

FIG. 41 is a cross-sectional configuration view of a semiconductor device according to a modification 3 of the present technology.

FIG. 42A is a view schematically illustrating a cross-sectional configuration of the semiconductor device of the modification 4 of the present technology. FIGS. 42B and 42C are views illustrating a planar configuration example of the semiconductor device according to the modification 4 of the present technology.

FIGS. 43A and 43B are cross-sectional views for each process of the manufacturing method of the configuration example 2 of the semiconductor device of the present technology.

FIG. 44A to 44C are cross-sectional views for each process of the manufacturing method of the configuration example 2 of the semiconductor device of the present technology.

FIGS. 45A and 45B are cross-sectional views for each process of the manufacturing method of the configuration example 2 of the semiconductor device of the present technology.

FIGS. 46A to 46C are views respectively schematically illustrating cross-sectional configurations of the semiconductor devices according to the modifications 5 to 7 of the semiconductor device of the present technology.

FIGS. 47A and 47B are views respectively schematically illustrating cross-sectional configurations of the semiconductor devices according to the modifications 8 and 9 of the semiconductor device of the present technology.

FIG. 48 is a diagram illustrating use examples of an electronic device including the semiconductor device according to the embodiment of the present technology.

FIG. 49 is a functional block diagram of an example of the electronic device including the semiconductor device according to the embodiment of the present technology.

FIG. 50 is a block diagram illustrating an example of a schematic configuration of a vehicle control system.

FIG. 51 is an explanatory diagram illustrating an example of installation positions of an outside-vehicle information detection unit and an imaging unit.

FIG. 52 is a view illustrating an example of a schematic configuration of an endoscopic surgery system.

FIG. 53 is a block diagram illustrating an example of a functional configuration of a camera head and a camera control unit (CCU).

### MODE FOR CARRYING OUT THE INVENTION

A favorable embodiment of the present technology will be described in detail with reference to the appended drawings. Note that, in the present specification and the drawings, components having substantially the same functional configurations are denoted by the same reference signs, and redundant descriptions are omitted. The embodiment to be described below provides a representative embodiment of the present technology, and the scope of the present technology is not to be narrowly interpreted according to the embodiment. In the present specification, even in a case where it is described that a semiconductor device according to the present technology exhibits a plurality of effects, the semiconductor device according to the present technology may exhibit at least one effect. The effects described in the present specification are merely examples and are not limited, and other effects may be exhibited.

Furthermore, the description will be given in the following order.
0. Introduction
1. Semiconductor Device According to Embodiment of Present Technology
2. Modifications of Present Technology
3. Other Modifications of Present Technology
4. Use Examples of Electronic Device Including Semiconductor Device According to Embodiment of Present Technology
5. Other Use Examples of Electronic Device Including Semiconductor Device According to Embodiment of Present Technology
6. Application Examples to Mobile Objects
7. Application Example to Endoscopic Surgery System

### 0. Introduction

### (Stacked CIS)

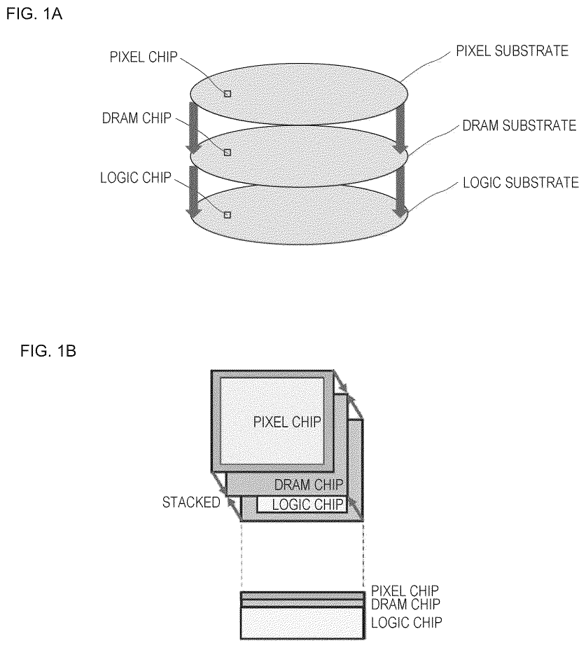

In recent years, various functions have been added to image sensors (solid-state imaging devices), and for example, a stacked CMOS image sensor having a three-layer structure (hereinafter, abbreviated as a “stacked CIS”) equipped with a dynamic random access memory (DRAM) in order to support super slow motion, and the like have been commercially available (see FIGS. 1A and 1B). The stacked CIS has a stacked structure in which, for example, a pixel chip, a DRAM chip, and a logic chip are stacked. The stacked CIS is used by being divided into units of chips by dicing after the three layers are stacked in units of wafers.

In the stacked CIS, a pixel substrate (a substrate integrally including a plurality of pixel chips in a series), a DRAM substrate (a substrate integrally including a plurality of DRAM chips in a series), and a logic substrate (a substrate integrally including a plurality of logic chips in a series) may not have the same size, but have the same size because the same size is preferable from the viewpoint of efficiency. Meanwhile, each chip needs to be designed with the same size in order to make the size after division be the same.

Meanwhile, for example, even in a case where the size of the DRAM chip calculated from a required DRAM capacity is not the same as the size of the pixel chip according to a product specification, the size of the DRAM chip needs to be matched with the size of the pixel chip. In this case, suppression of the size of the DRAM chip to a necessary size leads to cost reduction.

### (CoW)

Therefore, to reduce the cost, it is conceivable to bond a chip of a general-purpose size to a substrate instead of bonding substrates to each other. In this case, it is also possible to mount a chip having another function in a remaining space of the substrate to enhance the function. Stacking a chip on a wafer (substrate) is called chip on wafer (CoW).

In a conventional hybrid IC or the like, after a chip is attached to a base substrate, electrodes of the substrate and the chip are electrically connected by wire bonding or the like, but a connection region is required outside the chip, and a space is wasted. Furthermore, work of wire bonding takes time, which leads to an increase in cost.

### (Metal Bonding)

Therefore, there has also been developed a technique of using metal bonding (for example, Cu—Cu bonding) in which a connection terminal exposed on a bonding surface of a substrate to a chip and a connection terminal exposed on a bonding surface of the chip to the substrate are bonded to perform electrical connection, thereby securing the electrical connection at the same time as bonding of the substrate to the chip. By using this technique, the connection region outside the chip becomes unnecessary, and furthermore, the electrical connection can be performed at the same time as bonding, so that work time for electrical connection is not required, leading to cost reduction.

(Outline of Positional Shift Measurement in a Case Where WoW is performed by Metal Bonding)

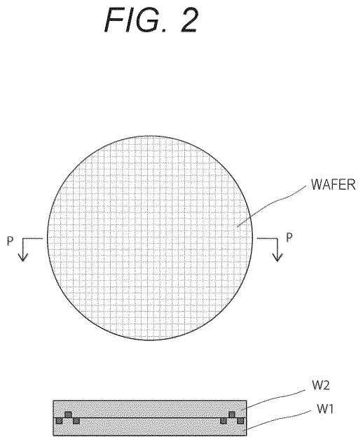

In a case where substrates W1 and W2 having wafer sizes are stacked as they are as in a conventional stacked structure illustrated in the lower view of FIG. 2 (the cross-sectional view taken along line P-P in the upper view of FIG. 2), it is not necessary to measure the positional shift in units of chips as long as the positional shift between the substrates is measured at two or more points in the substrate as a representative. In general, since a substrate includes Si, it is possible to irradiate the stacked structure with infrared rays having a long wavelength, receive the infrared rays transmitted through the substrate by an image sensor having sensitivity to the infrared rays, and measure the positional shift between the substrates at two or more points in the substrate. Moreover, at the time of bonding, since the substrate other than the base substrate is thinned, it is possible to cause the infrared rays to be transmitted through the substrate. By using copper or aluminum of a wiring material as a material for measuring the positional shift, it is possible to reflect the infrared rays.

(Details of Positional Shift Measurement in a Case Where Wow is performed by Metal Bonding)

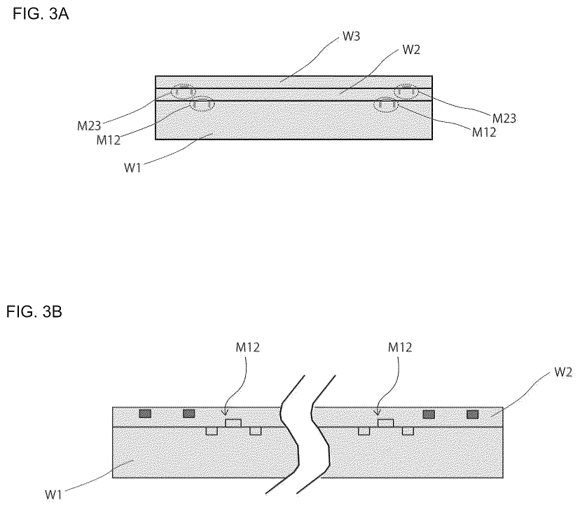

FIG. 3A illustrates a stacked structure (three-layer structure) provided with marks for measuring positional shift between substrates. This stacked structure is provided with a mark pair M12 for measuring the positional shift between the first and second substrates W1 and W2 and a mark pair M23 for measuring the positional shift between the second and third substrates W2 and W3. The mark pair M12 includes a mark formed on the first substrate W1 and a mark formed on the second substrate W2. The mark pair M23 includes a mark formed on the second substrate W2 and a mark formed on the third substrate W3. Each mark is formed using, for example, an electrode material for Cu—Cu bonding or a material for a wiring layer.

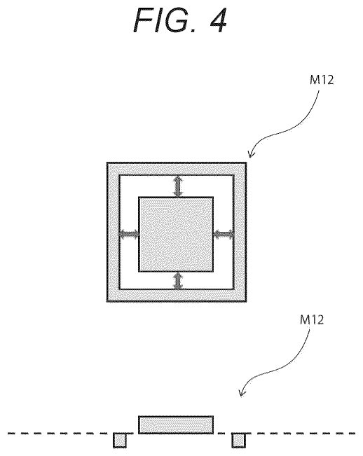

FIG. 3B is an enlarged view of a vicinity of the mark pair M12 when the first and second substrates W1 and W2 are bonded together. The dark color mark in FIG. 3B is the mark formed on the second substrate W2 of the mark pair M23. After temporarily bonding the first and second substrates W1 and W2, the mark pair M12 is measured to measure a positional shift amount of the first and second substrates W1 and W2. When the positional shift amount is equal to or less than a reference value, it is determined as pass, and a process for permanent bonding is performed, but when the positional shift amount exceeds the reference value, the first and second substrates W1 and W2 are bonded again, and the mark pair M12 is measured again. An image of the mark at the time of measurement captured by a measuring instrument is in a state as illustrated in the upper view of FIG. 4 (plan view) and in the lower view of FIG. 4 (cross-sectional view), and it is possible to calculate the positional shift amount of the first and second substrates W1 and W2 by measuring dimensions of portions indicated by the arrows in the upper view of FIG. 4. At this time, a rotation component is also included. Therefore, it is possible to suppress the positional shift amount of the first and second substrates W1 and W2 to be equal to or less than the reference value regardless of a positional shift direction by measuring two or more mark pairs M12. It is only required to perform a similar process when bonding the third substrate W3 to the second substrate W2. Therefore, in the case of bonding the substrates to each other, it is sufficient to measure two or more points (two or more marks), and it is not necessary to measure the positional shift in all units of chips.

### (Positional Shift Measurement When CoC or CoW Is Performed by Metal Bonding)

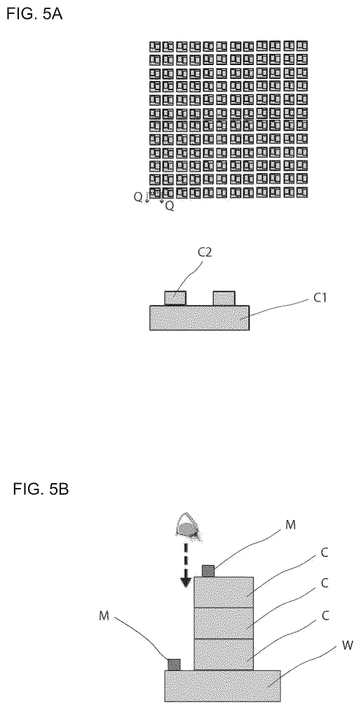

Also in a case of chi on chip (CoC) or Cow illustrated in the upper view (plan view) of FIG. 5A and the lower view of FIG. 5A (cross-sectional view taken along line Q-Q of the upper view of FIG. 5A), it is possible to measure the positional shift between a chip C1 or wafer of a lower layer and a chip C2 of an upper layer by light transmission using marks. However, for example, in a case of a multilayer structure (for example, a composite structure of CoW and CoC) illustrated in FIG. 5B (cross-sectional view), the marks cannot be measured by light transmission. Therefore, relative positions of the marks M formed on the wafer W and the chip C are directly measured, but in this case, the measurement accuracy may be deteriorated.

By the way, in CoC or CoW, even if the measurement is not performed in all units of chips, it is possible to confirm whether or not bonding has been performed by checking a function of an LSI by electrical function inspection. For example, in a case where a logic chip or a memory chip is bonded to a pixel chip or a pixel substrate, when the pixel chip or the pixel substrate is irradiated with light and signals are obtained from all of pixels (pixels), it is possible to confirm that the bonding has been performed. However, it is not possible to confirm whether or not there is no problem in the future.

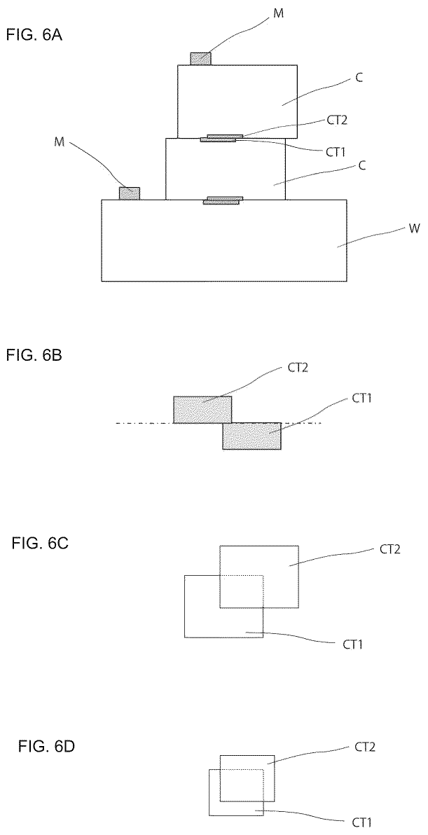

For example, in the multilayer structure as illustrated in FIG. 6A, even in a case where a connection terminal CT1 on a chip C side of an intermediate layer and a connection terminal CT2 on the chip C side of an upper layer are bonded in a state where a contact area is significantly small (see FIG. 6B), it is determined as pass in electrical function inspection. However, deterioration proceeds by an influence of heat generation or the like due to an increase in contact resistance due to the small contact area, and there is a possibility that a life becomes shorter than a normal life. Therefore, in CoC and CoW, it is desirable to measure the positional shift in units of chips.

However, in the case of measuring the positional shift in all units of chips, it takes a long time to perform the measurement, which may lead to an increase in cost.

### (Method of Increasing Size of Connection Terminal)

Therefore, as illustrated in FIG. 6C, it is conceivable to increase the sizes of the connection terminals CT1 and CT2 in advance by a maximum allowable positional shift amount (allowable value) between the layers to be bonded. Thereby, even if the inspection is not performed in all units of chips, a bonding area between the connection terminals can be sufficiently obtained in all the chips. Therefore, a defect in which the contact area as illustrated in FIG. 6B is significantly reduced does not occur. However, if the sizes of all the connection terminals are increased by the above-described allowable value, a chip size becomes larger than a scheduled size, which leads to an increase in cost.

From the above consideration, as illustrated in FIG. 6D, it is desired to provide a semiconductor device capable of quickly and accurately detecting the positional shift between layers (semiconductor structures) to be bonded while suppressing the size of at least one (for example, both) of the connection terminals CT1 and CT2 to be small (while suppressing the chip size to be small).

### Object of Present Technology

Therefore, as a result of intensive studies, the inventors have developed a semiconductor device according to the present technology as a semiconductor structure capable of quickly and accurately detecting positional shift of the first and second semiconductor structures while suppressing an increase in size of the first semiconductor structure and/or the second semiconductor structure.

### <<1. Semiconductor Device According to Embodiment of Present Technology>>

Hereinafter, a semiconductor device according to an embodiment of the present technology will be described with reference to the drawings. First, an outline of a semiconductor device according to an embodiment of the present technology will be described using configuration examples 1 and 2 as examples.

### Configuration Example 1

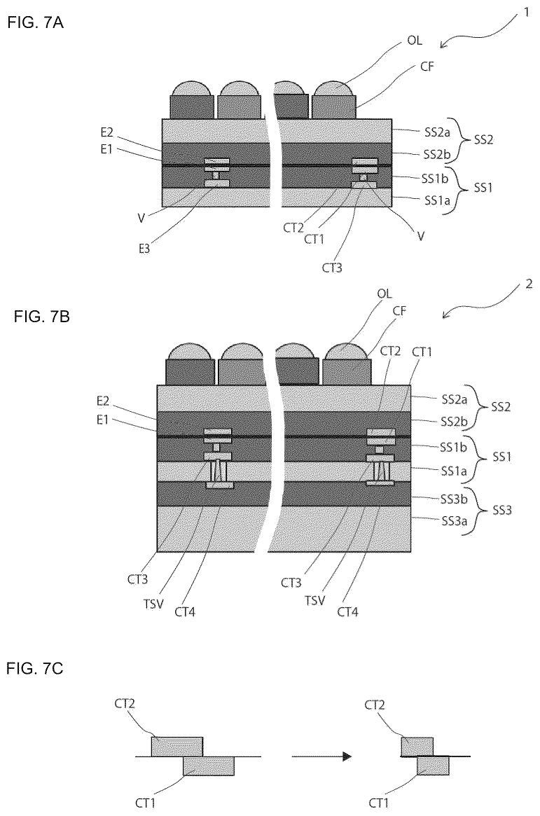

FIG. 7A is a view schematically illustrating a cross-sectional configuration of the configuration example 1 of the semiconductor device according to the embodiment of the present technology. As illustrated in FIG. 7A, a semiconductor device 1 of the configuration example 1 constitutes a back-illuminated solid-state imaging device (image sensor) as an example. The semiconductor device 1 has a stacked structure (for example, a two-layer structure) in which a first semiconductor structure SS1 and a second semiconductor structure SS2 are stacked and bonded. The first semiconductor structure SS1 includes a first semiconductor substrate SS1a and a first wiring layer SS1b that are electrically connected. The second semiconductor structure SS2 includes a second semiconductor substrate SS2a and a second wiring layer SS2b that are electrically connected. In the first and second semiconductor structures SS1 and SS2, the first and second wiring layers SS1b and SS2b are bonded facing each other. That is, a bonding surface of the first semiconductor structure SS1 to the second semiconductor structure SS2 is a bonding surface of the first wiring layer SS1b to the second wiring layer SS2b, and a bonding surface of the second semiconductor structure SS2 to the first semiconductor structure SS1 is a bonding surface of the second wiring layer SS2b to the first wiring layer SS1b. As an example, the first semiconductor structure SS1 is a logic chip in which a logic circuit is formed on the first semiconductor substrate SS1a. As an example, the second semiconductor structure SS2 is a pixel chip in which a plurality of pixels each having a photoelectric conversion element (for example, a photodiode (PD)) is arranged in an array on the second semiconductor substrate SS2a. On the second semiconductor substrate SS2a, a color filter CF and an on-chip lens OL are provided for each pixel.

The first semiconductor structure SS1 has a first connection terminal CT1 exposed to a first bonding surface JS1 that is a bonding surface to the second semiconductor structure SS2, and the second semiconductor structure SS2 has a second connection terminal CT2 exposed to a second bonding surface JS2 that is a bonding surface to the first semiconductor structure SS1 and bonded to the first connection terminal CT1 by, for example, metal bonding. The stacked structure includes a first electrode E1 provided in the first semiconductor structure SS1 and capable of changing an electrical characteristic with respect to the second semiconductor structure SS2 according to the positional shift between the first connection terminal CT1 and the second connection terminal CT2, and a second electrode E2 provided in the second semiconductor structure SS2 and capable of changing an electrical characteristic with respect to the first semiconductor structure SS1 according to the positional shift. The first connection terminal CT1 is connected to a third connection terminal CT3 provided to be exposed to a surface of the first wiring layer SS1b on a first semiconductor substrate SS1a side via a via V. The first electrode E1 is connected to a third electrode E3 provided to be exposed to a surface of the first wiring layer SS1b on the first semiconductor substrate SS1a side via a via V.

More specifically, the first electrode E1 is provided in the first semiconductor structure SS1 so as to be exposed to the first bonding surface JS1, and a state of the first electrode E1 is variable between a state of being in conduction with the second semiconductor structure SS2 and a state of being not in conduction with the second semiconductor structure SS2 according to the positional shift of the first and second connection terminals CT1 and CT2. The second electrode E2 is provided in the second semiconductor structure SS2 so as to be exposed to the second bonding surface JS2, and a state of the second electrode E2 is variable between a state of being in conduction with the first semiconductor structure SS1 and a state of being not in conduction with the first semiconductor structure SS1 according to the positional shift of the first and second connection terminals CT1 and CT2.

More specifically, the first and second electrodes E1 and E2 are disposed at positions where the states of the first and second electrodes E1 and E2 are changeable between a contact state of being in contact with each other and a non-contact state of being not in contact with each other according to the positional shift of the first and second connection terminals CT1 and CT2.

Specifically, the states of the first and second electrodes E1 and E2 are different between the contact state of being in contact with each other and the non-contact state of being not in contact with each other between when the positional shift of the first and second connection terminals CT1 and CT2 is equal to or less than a predetermined value (for example, an allowable value) and when the positional shift exceeds the predetermined value.

For example, the first and second electrodes E1 and E2 are disposed at positions where the first and second electrodes E1 and E2 are in contact with each other when the positional shift between the first and second connection terminals CT1 and CT2 is equal to or less than the predetermined value (for example, the allowable value), and are not in contact with each other when the positional shift exceeds the predetermined value. Note that the first and second electrodes E1 and E2 may be disposed at positions where the first and second electrodes E1 and E2 are not in contact with each other when the positional shift between the first and second connection terminals CT1 and CT2 is equal to or less than the predetermined value (for example, the allowable value), and are in contact with each other when the positional shift exceeds the predetermined value.

In the semiconductor device 1 of the first configuration example, it is possible to detect whether or not the positional shift of the first and second connection terminals CT1 and CT2 is equal to or less than the predetermined value (for example, the allowable value) by performing conduction inspection of the first and second electrodes E1 and E2. According to the semiconductor device 1, it is possible to quickly and accurately detect the positional shift of the first and second connection terminals CT1 and CT2.

### Configuration Example 2

FIG. 7B is a view schematically illustrating a cross-sectional configuration of a configuration example 2 of the semiconductor device according to the embodiment of the present technology. As illustrated in FIG. 7B, a semiconductor device 2 of the second configuration example has a stacked structure (three-layer structure) in which the first semiconductor structure SS1, the second semiconductor structure SS2, and a third semiconductor structure SS3 are stacked. The semiconductor device 2 of the second configuration example has a configuration in which the third semiconductor structure SS3 is bonded to a surface (lower surface) of the first semiconductor structure SS1 of the semiconductor device 1 of the first configuration example on a side opposite to a second semiconductor structure SS2 side. The third semiconductor structure SS3 includes a third semiconductor substrate SS3a and a third wiring layer SS3b that are electrically connected. As an example, the third semiconductor structure SS3 is a memory chip in which a memory circuit is formed on the third semiconductor substrate SS3a. The third wiring layer SS3b is stacked below the first semiconductor substrate SS1a. The third connection terminal CT3 is connected to a fourth connection terminal CT4 provided to be exposed to a surface of the third wiring layer SS3b on the first semiconductor substrate SS1a side via a through electrode TSV penetrating the first semiconductor substrate SS1a.

### Effects of Semiconductor Devices of Configuration Examples 1 and 2

According to the semiconductor devices 1 and 2 of the first and second configuration examples described above, it is possible to quickly and accurately detect the positional shift between the first and second connection terminals CT1 and CT2 while reducing the sizes of the connection terminals of the first connection terminals CT1 and CT2 (while suppressing an increase in size of the first and second semiconductor structures SS1 and SS2), as illustrated in FIG. 7C.

Next, details of a semiconductor device according to an embodiment of the present technology will be described with some examples.

### Example 1

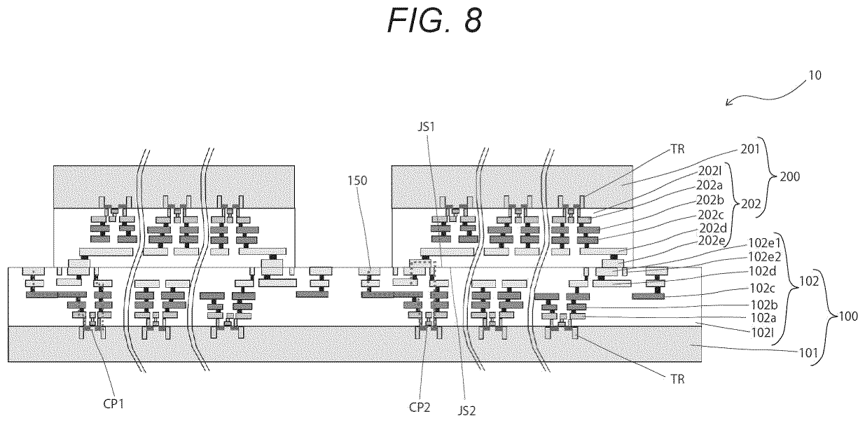

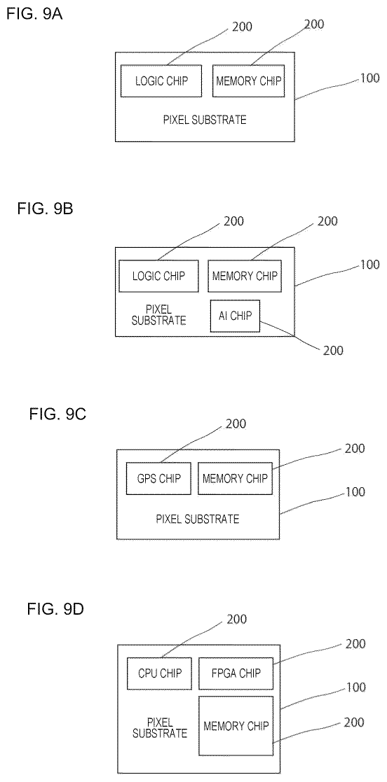

FIG. 8 is a view schematically illustrating a cross-sectional configuration of a semiconductor device 10 according to an example 1 of the embodiment of the present technology. FIGS. 9A to 9D are diagrams schematically illustrating a planar configuration example of the semiconductor device 10 according to the example 1 of the embodiment of the present technology.

### (Overall Configuration)

The semiconductor device 10 constitutes a back-illuminated solid-state imaging device (image sensor), as an example. As an example, the semiconductor device 10 has a stacked structure (for example, a two-layer structure) in which first and second semiconductor structures 100 and 200 are stacked and bonded. As an example, in the semiconductor device 10, a plurality (for example, two) of the second semiconductor structures 200 is stacked on the first semiconductor structure 100 by CoW, for example. That is, the second semiconductor structure 200 is smaller than the first semiconductor structure 100.

The first semiconductor structure 100 includes a first semiconductor substrate 101 and a first wiring layer 102 that are stacked. The second semiconductor structure 200 includes a second semiconductor substrate 201 and a second wiring layer 202 that are stacked. In the first and second semiconductor structures 100 and 200, the first and second wiring layers 102 and 202 are bonded facing each other.

The first semiconductor structure 100 includes a first connection terminal 102e1 exposed to a first bonding surface JS1 that is a bonding surface to the second semiconductor structure 200. The second semiconductor structure 200 includes a second connection terminal 202e exposed to a second bonding surface JS2 that is a bonding surface to the first semiconductor structure 100, and bonded to the first connection terminal 102e1. The sizes of the first and second connection terminals 102e1 and 202e are, for example, substantially the same.

Examples of the first connection terminal 102e1 include one for supplying power to the second semiconductor structure 200 (for power line) and one for exchanging signals with the second semiconductor structure 200 (for signal line). Examples of the second connection terminal 202e include one for receiving power supply from the first semiconductor structure 100 (for power line) and one for exchanging signals with the first semiconductor structure 200 (for signal line).

The stacked structure includes a first electrode 102e2 provided in the first semiconductor structure 100, and capable of changing an electrical characteristic with respect to the second semiconductor structure 200 according to the positional shift of the first and second connection terminals 102e1 and 202e. The first electrode 102e2 may be referred to as an “inspection electrode” because it is used for inspecting the positional shift.

Specifically, the first electrode 102e2 is provided in the first semiconductor structure 100 so as to be exposed to the first bonding surface JS1, and the state of the first electrode 102e2 is variable between the state of being in conduction with the second semiconductor structure 200 and the state of being not in conduction with the second semiconductor structure 200 according to the positional shift of the first and second connection terminals 102e1 and 202e.

More specifically, the first electrode 102e2 is disposed at a position where the state of the first electrode 102e2 is changeable between the contact state of being in contact with the second connection terminal CT2 and the non-contact state of being not in contact with the second connection terminal CT2 according to the positional shift of the first and second connection terminals 102e1 and 202e.

Specifically, the state of the first electrodes 102e2 is different between the contact state of being in contact with the second connection terminal 202e and the non-contact state of being not in contact with the second connection terminal 202e between when the positional shift of the first and second connection terminals 102e1 and 202e is equal to or less than a predetermined value (for example, an allowable value) and when the positional shift exceeds the predetermined value.

### (First Semiconductor Structure)

The first semiconductor substrate 101 is provided with a pixel unit as an example. The pixel unit includes a plurality of pixels that is two-dimensionally arranged as an example. Each pixel includes at least one photoelectric conversion element (for example, a photodiode (PD)). Each pixel is a back-illuminated pixel irradiated with light from a back side of the first semiconductor substrate 101. A color filter and an on-chip lens may be provided for each pixel on a back surface (a surface opposite to the first wiring layer 102 side) of the first semiconductor substrate 101. The first semiconductor substrate 101 is, for example, a Si substrate, a Ge substrate, a GaAs substrate, an InGaAs substrate, or the like. The first semiconductor structure 100 is also called, for example, a pixel substrate.

The first semiconductor substrate 101 is further provided with, as an example, a control circuit (analog element) that controls the plurality of pixels, and an A/D converter (analog circuit) that A/D converts an electric signal (analog signal) output from the pixel unit.

The control circuit includes, for example, a circuit element such as a transistor. More specifically, as an example, the control circuit includes a plurality of pixel transistors (so-called MOS transistors). The plurality of pixel transistors can include three transistors of a transfer transistor, a reset transistor, and an amplification transistor, for example. In addition, the plurality of pixel transistors can include four transistors by adding a selection transistor. Since an equivalent circuit of a unit pixel is similar to a normal circuit, detailed description thereof is omitted. The pixel can be configured as one unit pixel. Furthermore, the pixel may have a shared pixel structure. This pixel sharing structure is a structure in which a plurality of photodiodes shares a floating diffusion constituting a transfer transistor and another transistor other than the transfer transistor.

As an example, the first wiring layer 102 is a multilayer wiring layer in which a plurality of internal wirings 102a, 102b, 102c, and 102d are stacked in this order from a first semiconductor substrate 101 side in an insulating film 102I. The internal wirings adjacent in a stacking direction are connected via vias. The internal wiring 102d is connected to the first connection terminal 102e1 via a via. The internal wiring 102a is connected to a land provided to be exposed to the surface of the first semiconductor substrate 101 on the first wiring layer 102 side via a via. A shallow trench isolation-type trench TR for preventing a leakage current between elements is formed around the land on the surface of the first semiconductor substrate 101 on the first wiring layer 102 side. Each internal wiring includes, for example, Cu, Al, W, Au, Co, Ta, Ti, or the like, and the insulating film 102I includes, for example, a silicon oxide film, a silicon nitride film, or the like. An electrode pad 150 is provided to be exposed to a portion of the first bonding surface JS1 around the second semiconductor structure 200. The electrode pad 150 is connected to the internal wiring 102d via a via.

### (Second Semiconductor Structure)

As an example, each second semiconductor structure 200 is a chip including a processing circuit that processes a signal output from the pixel unit. The second semiconductor structure 200 is, for example, any of a logic chip including a logic circuit, a memory chip, an analog chip (for example, a chip including the above-described control circuit, A/D converter, and the like), a GPS chip, a CPU chip, an FPGA chip, an interface chip, or an AI chip. Note that the interface chip includes an interface circuit that inputs and outputs signals. The AI chip includes an artificial intelligence (AI) circuit having a learning function based on AI. Note that the plurality of second semiconductor structures 200 may be, for example, a logic chip and a memory chip stacked on the pixel substrate as the first semiconductor structure 100 (see FIG. 9A), may be, for example, a logic chip, a memory chip, and an AI chip stacked on the pixel substrate as the first semiconductor structure 100 (see FIG. 9B), may be, for example, a GPS chip and a memory chip stacked on the pixel substrate as the first semiconductor structure 100 (see FIG. 9C), or may be, for example, a CPU chip, an FPGA chip, and a memory chip stacked on the pixel substrate as the first semiconductor structure 100 (see FIG. 9D). The combination of chips as the plurality of second semiconductor structures 200 is not limited to the above, and can be appropriately changed.

Here, a case where one of the plurality of second semiconductor structures 200 is a logic chip will be described as an example. As an example, the second semiconductor substrate 201 is provided with a logic circuit, and the logic circuit is electrically connected to the second wiring layer 202. The logic circuit includes a transistor, and processes a digital signal obtained by A/D converting an analog signal output from the pixel unit by an A/D converter. The second semiconductor substrate 201 is, for example, a Si substrate, a Ge substrate, a GaAs substrate, an InGaAs substrate, or the like.

As an example, the second wiring layer 202 is a multilayer wiring layer in which a plurality of internal wirings 202a, 202b, 202c, and 202d are stacked in this order from a second semiconductor substrate 201 side in an insulating film 202I. The internal wirings adjacent in a stacking direction are connected via vias. The internal wiring 202d is connected to the second connection terminal 202e via a via. The internal wiring 202a is connected to a land provided to be exposed to the surface of the second semiconductor substrate 201 on a second wiring layer 202 side via a via. A shallow trench isolation-type trench TR for preventing a leakage current between elements is formed around the land on the surface of the second semiconductor substrate 201 on the second wiring layer 202 side. Each internal wiring includes, for example, Cu, Al, W, Au, Co, Ta, Ti, or the like, and the insulating film 202I includes, for example, a silicon oxide film, a silicon nitride film, or the like.

### (Inspection Circuit)

The first semiconductor structure 100 is provided with a general inspection circuit (an inspection circuit for checking pass/fail of a normal semiconductor circuit). In the first semiconductor structure 100, the inspection circuit and the first electrode 102e2 as an inspection electrode may be electrically connected. For example, in a case where the first electrode 102e2 and the inspection circuit that senses a flow of a current are connected, it can be determined as pass when the current flows, and it can be determined as fail when the current does not flow.

### (Example of Positional Shift Detection)

As illustrated in FIG. 8, as an example, the positional shift between the first semiconductor structure 100 and the second semiconductor structure 200 on the left side is equal to or less than the allowable value, and the second connection terminal 202e and the first electrode 102e2 are not in contact with each other. At this time, for example, when the current is injected into the first wiring layer 102 via the electrode pad 150 located around the second semiconductor structure 200, a current path CP1 (see the broken line on the left side of FIG. 8) is generated in the first semiconductor structure 100, but the current does not flow through the second semiconductor structure 200, and the processing circuit in the second semiconductor structure 200 does not operate.

Meanwhile, as illustrated in FIG. 8, as an example, the positional shift between the first semiconductor structure 100 and the second semiconductor structure 200 on the right side exceeds the allowable value, and the second connection terminal 202e and the first electrode 102e2 are in contact with each other. At this time, for example, when the current is injected into the first wiring layer 102 via the electrode pad 150 located around the second semiconductor structure 200, a current path CP2 (see the broken line on the right side of FIG. 8) is generated in the first semiconductor structure 100, and the current flows through the second semiconductor structure 200, and the processing circuit in the second semiconductor structure 200 operates. In other words, when the current is injected into the first wiring layer 102 via the electrode pad 150, and in the case where the processing circuit does not operate, it can be estimated that the positional shift of the first and second semiconductor structures 100 and 200 is equal to or less than the allowable value (it can be determined as pass), and in the case where the processing circuit operates, it can be estimated that the positional shift of the first and second semiconductor structures 100 and 200 exceeds the allowable value (it can be determined as fail).

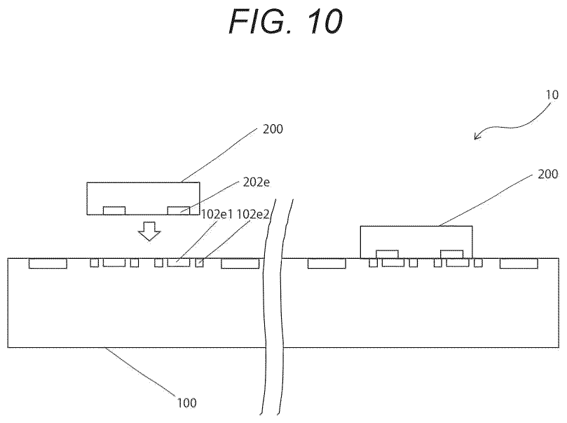

By the way, in the semiconductor device 10, as illustrated in FIG. 10 as an example, the second semiconductor structure 200 is bonded (temporarily bonded or fully bonded) to the first semiconductor structure 100 at the time of manufacturing. After the bonding, the positional shift of the first and second connection terminals can be inspected using a positional shift detection system including the inspection electrode. Hereinafter, some configuration examples of the positional shift detection system will be described. Note that FIG. 8 representatively illustrates a configuration example 1 of the positional shift detection system to be described below.

### Configuration Example 1 of Positional Shift Detection System

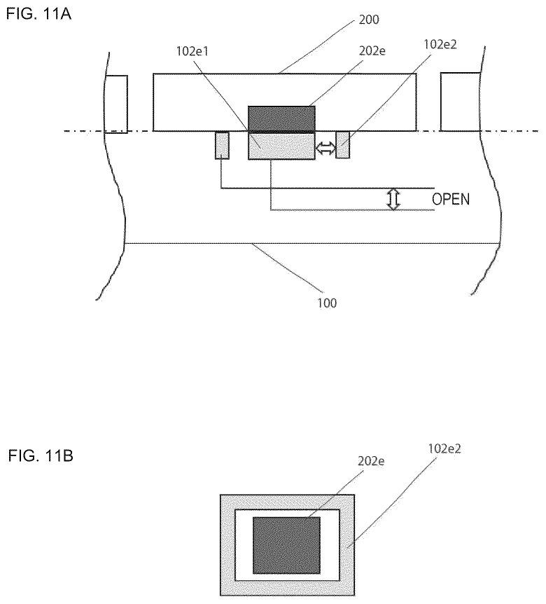

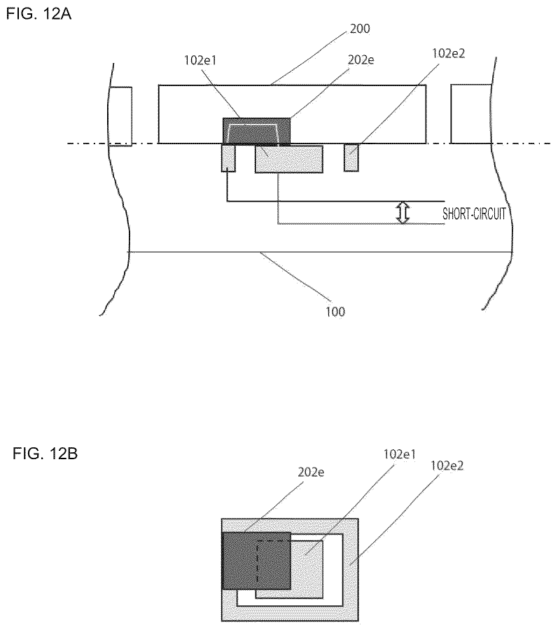

FIGS. 11A and 11B are respectively a cross-sectional view and a plan view illustrating the configuration example 1 of the positional shift detection system when the first connection terminal 102e1 and the first electrode 102e2 are in an open state. FIGS. 12A and 12B are respectively a cross-sectional view and a plan view illustrating the configuration example 1 of the positional shift detection system when the first connection terminal 102e1 and the first electrode 102e2 are in a short-circuit state.

In the configuration example 1 of the positional shift detection system, the first electrode 102e2 is provided in a frame shape so as to surround the first connection terminal 102e1, as illustrated in FIGS. 11A and 11B. As an example, a clearance between the first electrode 102e2 and the first connection terminal 102e1 is set to a predetermined value (for example, an allowable value) equal to or less than the allowable value (maximum allowable positional shift amount) of the positional shift between the first and second connection terminals 102e1 and 202e. Note that, in a case where the positional shift between the first and second connection terminals 102e1 and 202e is much larger than the allowable value, the circuit formed on the substrate or the chip does not operate, and thus an abnormality is found.

The state of the first electrodes 102e2 is different between the contact state of being in contact with the second connection terminal 202e and the non-contact state of being not in contact with the second connection terminal 202e between when the positional shift of the first and second connection terminals 102e1 and 202e is equal to or less than the above-described predetermined value and when the positional shift exceeds the predetermined value, as illustrated in FIGS. 11A and 11B, for example.

For example, in the state illustrated in FIGS. 11A and 11B, the positional shift between the first and second connection terminals 102e1 and 202e is equal to or less than the above-described predetermined value, and the first electrode 102e2 is in a non-contact state with (is in an electrically insulated state from) the second connection terminal 202e. In this case, even when a voltage is applied between the first connection terminal 102e1 and the first electrode 102e2, no current flows.

Meanwhile, in the configuration example 1 of the positional shift detection system, in the state illustrated in FIGS. 12A and 12B, the positional shift of the first and second connection terminals 102e1 and 202e exceeds the above-described predetermined value, and the first electrode 102e2 is in a contact state with (is in an electrically connected state to) the second connection terminal 202e. In this case, when a voltage is applied between the first connection terminal 102e1 and the first electrode 102e2, a current flows through the second connection terminal 202e. In a case where the case where the current flows is determined as fail, the state illustrated in FIGS. 11A and 11B can be determined as pass, and the state illustrated in FIGS. 12A and 12B can be determined as fail. Furthermore, even if the first electrode 102e2 as an inspection electrode is provided only at one location, in a case where shift in rotation about the inspection electrode happens to occur in the first and second connection terminals 102e1 and 202e, no current flows in the inspection electrode located at the center, and thus it is determined as pass. However, in a case where another inspection electrode is provided at a location far away from the inspection electrode, a current may flow in the another inspection electrode when similar shift in rotation occurs. Therefore, it is preferable that the inspection electrodes are provided at least at two locations.

### Configuration Example 2 of Positional Shift Detection System

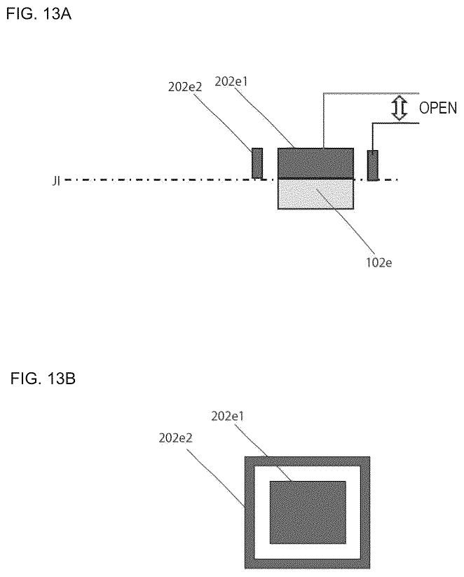

In a configuration example 2 of the positional shift detection system, a second electrode 202e2 as an inspection electrode is provided in the second semiconductor structure 200, as illustrated in FIGS. 13A (cross-sectional view) and 13B (plan view). In FIG. 13A, the alternate long and short dash line represents a bonding interface JI of the first and second semiconductor structures 100 and 200.

The second electrode 202e2 is provided in a frame shape so as to surround a second connection terminal 202e1. As an example, the clearance between the second electrode 202e2 and the second connection terminal 202e1 is set to a predetermined value (for example, an allowable value) equal to or less than the allowable value (maximum allowable positional shift amount) of the positional shift between first and second connection terminals 102e and 202e1.

In the state illustrated in FIGS. 13A and 13B, the positional shift between the first and second connection terminals 102e and 202e1 is equal to or less than the above-described predetermined value, and the second electrode 202e2 and the first connection terminal 102e are in a non-contact state (are in an electrically insulated state). In this case, even when a voltage is applied between the second connection terminal 202e1 and the second electrode 202e2, no current flows.

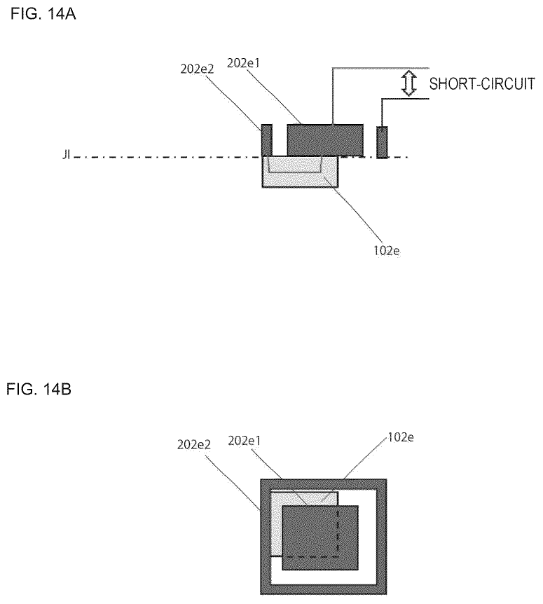

Meanwhile, in the state illustrated in FIGS. 14A (cross-sectional view) and 14B (plan view), the positional shift between the first and second connection terminals 102e and 202e1 exceeds the above-described predetermined value, and the second electrode 202e2 and the first connection terminal 102e are in a contact state (in an electrically connected state). In this case, when a voltage is applied between the second connection terminal 202e1 and the second electrode 202e2, a current flows through the first connection terminal 102e. In the case where the case where the current flows is determined as fail, the state illustrated in FIGS. 13A and 13B can be determined as pass, and the state illustrated in FIGS. 14A and 14B can be determined as fail. Furthermore, even if the second electrode 202e2 as an inspection electrode is provided only at one location, in a case where shift in rotation about the inspection electrode happens to occur in the first and second connection terminals 102e and 202e1, no current flows in the inspection electrode located at the center, and thus it is determined as pass. However, in a case where another inspection electrode is provided at a location far away from the inspection electrode, a current may flow in the another inspection electrode when similar shift in rotation occurs. Therefore, it is preferable that the inspection electrodes are provided at least at two locations.

### Configuration Example 3 of Positional Shift Detection System

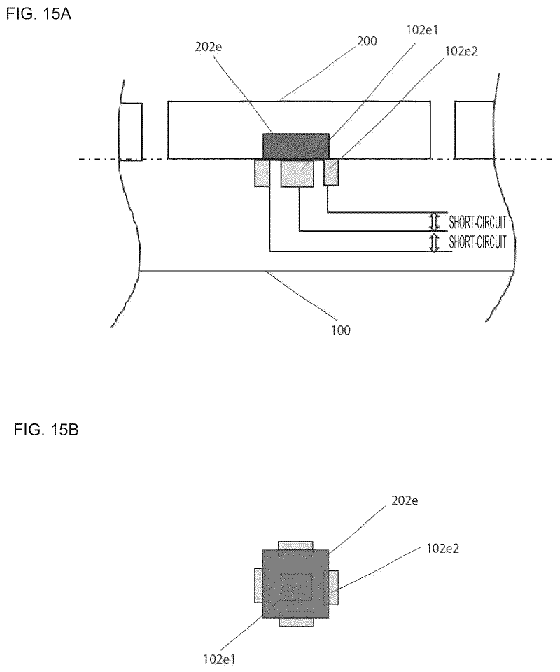

FIGS. 15A and 15B are respectively a cross-sectional view and a plan view illustrating a configuration example 3 of the positional shift detection system when the first connection terminal 102e1 and the first electrode 102e2 are in a short-circuit state.

In the configuration example 3 of the positional shift detection system, as an example, a plurality (for example, four) of the first electrodes 102e2 (inspection electrodes) are disposed so as to surround the first connection terminal 102e1 from four directions, as illustrated in FIGS. 15A and 15B. As an example, the second connection terminal 202e has a size capable of simultaneously coming in contact with the first connection terminal 102e1 and the four first electrodes 102e2. The clearance between the first connection terminal 102e1 and each of the first electrodes 102e2 is set to a predetermined value (for example, an allowable value) equal to or less than the allowable value of the positional shift of the first and second connection terminals 102e1 and 202e. The four first electrodes 102e2 are also collectively referred to as an “inspection electrode group”.

In the configuration example 3 of the positional shift detection system, some of the plurality of first electrodes 102e2 are different between the contact state of being in contact with the second connection terminal 202e and the non-contact state of being not in contact with the second connection terminal 202e between when the positional shift of the first and second connection terminals 102e1 and 202e is equal to or less than the above-described predetermined value and when the positional shift exceeds the predetermined value.

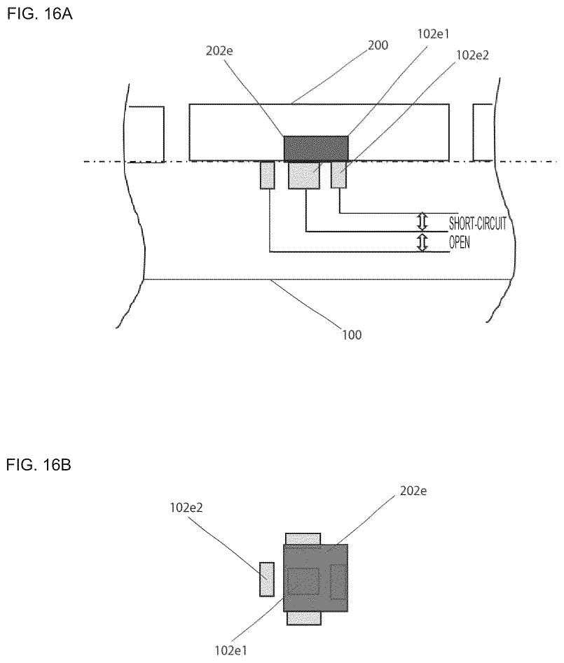

In configuration example 3 of the positional shift detection system, for example, when the positional shift of the first and second connection terminals 102e1 and 202e are equal to or less than the above-described predetermined value, the four first electrodes 102e2 and the second connection terminals 202e are in contact with each other, as in the state illustrated in FIGS. 15A and 15B. At this time, when a voltage is applied between the four first electrodes 102e2 and the first connection terminal 102e1, a current flows between each of the first electrodes 102e2 and the first connection terminal 102e1 via the second connection terminal 202e. Meanwhile, for example, in a case where the positional shift exceeding the predetermined value (for example, the allowable value) as illustrated in FIGS. 16A and 16B occurs, for example, one first electrode 102e2 and the second connection terminal 202e are brought into the non-contact state (electrically insulated state). At this time, when a voltage is applied between the four first electrodes 102e2 and the first connection terminal 102e1, no current flows between the one first electrode 102e2 and the first connection terminal 102e1, and thus it is possible to detect that the positional shift has exceeded the above-described predetermined value and detect the direction of the positional shift. That is, in the configuration example 3 of the positional shift detection system, the first connection terminal 102e1 and all the first electrodes 102e2 are determined as pass at the time of the short-circuit state, and the first connection terminal 102e1 and some of the first electrodes 102e2 are determined as fail at the time of the open state.

Furthermore, in the configuration example 3, in a case where a rotation center of the positional shift accompanying rotation is close to a center of the inspection electrode group, there is a possibility that the positional shift cannot be detected. Therefore, it is preferable to provide the inspection electrode groups at two or more locations. Note that, here, an example in which the inspection electrode group is provided in the first semiconductor structure 100 has been described, but the inspection electrode group may be provided in the second semiconductor structure 200. In this case, the second connection terminal 202e1 and each of the second electrodes 202e2 are determined as pass at the time of the short-circuit state, and the second connection terminal 202e1 and some of the second electrodes 202e2 are determined as fail at the time of the open state.

### Configuration Example 4 of Positional Shift Detection System

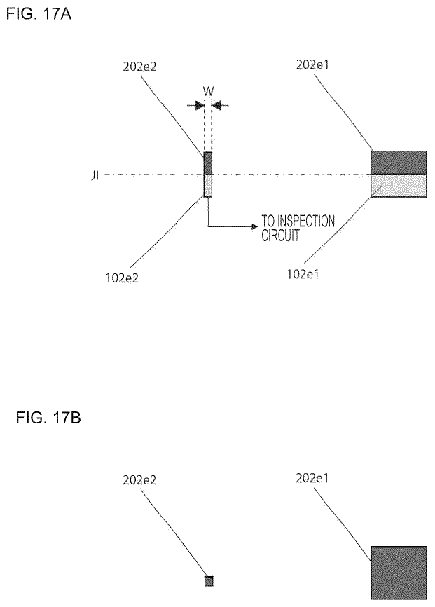

FIGS. 17A (cross-sectional view) and 17B (plan view) illustrate a state in which the positional shift of the first and second connection terminals 102e1 and 202e1 is equal to or less than a predetermined value (for example, an allowable value) (a state determined as pass) in a configuration example 4 of the positional shift detection system.

In the configuration example 4 of the positional shift detection system, the first electrode 102e2 as an inspection electrode is provided in the first semiconductor structure 100, and the second electrode 202e2 as an inspection electrode is provided in the second semiconductor structure 200, as illustrated in FIGS. 17A (cross-sectional view) and 17B (plan view).

The first and second electrodes 102e2 and 202e2 are disposed at positions where the states of the first and second electrodes 102e2 and 202e2 are changeable between the contact state of being in contact with each other and the non-contact state of being not in contact with each other according to the positional shift of the first and second connection terminals 102e1 and 202e1.

Specifically, the states of the first and second electrodes 102e2 and 202e2 are different between the contact state of being in contact with each other and the non-contact state of being not in contact with each other between when the positional shift of the first and second connection terminals 102e1 and 202e1 is equal to or less than a predetermined value (for example, an allowable value) and when the positional shift exceeds the predetermined value.

More specifically, the first and second electrodes 102e2 and 202e2 are in the contact state when the positional shift between the first and second connection terminals 102e1 and 202e1 is equal to or less than the predetermined value (for example, the allowable value), and are in the non-contact state when the positional shift exceeds the predetermined value. Note that the first and second electrodes 102e2 and 202e2 may be in the non-contact state when the positional shift between the first and second connection terminals 102e1 and 202e1 is equal to or less than the predetermined value (for example, the allowable value), and may be in the contact state when the positional shift exceeds the predetermined value.

As an example, the sizes of the first and second electrodes 102e2 and 202e2 are substantially the same size of the above-described predetermined value (for example, the allowable value) or less.

As illustrated in FIGS. 17A and 17B, when the positional shift between the first and second connection terminals 102e1 and 202e1 is 0, the first and second connection terminals 102e1 and 202e1 overlap, and the first and second electrodes 102e2 and 202e2 overlap.

In the configuration example 4, as an example, an inspection circuit is provided in the first semiconductor structure 100, and the inspection circuit and the first electrode 102e2 are electrically connected. The inspection circuit functions as a determination system that determines a change in electrical characteristics (for example, conduction/non-conduction) between the first and second electrodes 102e2 and 202e2.

The second electrode 202e2 is connected to the power line inside the second semiconductor structure 200. For example, in the state illustrated in FIGS. 17A and 17B, since the first electrode 102e2 (inspection electrode) provided in the first semiconductor structure 100 is in contact with (is electrically connected to) the second electrode 202e2 (inspection electrode) provided in the second semiconductor structure 200, a voltage is applied. Therefore, a current flows through the inspection circuit via the first electrode 102e2. Therefore, when the current flows through the inspection circuit, it can be determined as pass. Note that a signal line in which some potential difference is generated may be used instead of the above-described power line.

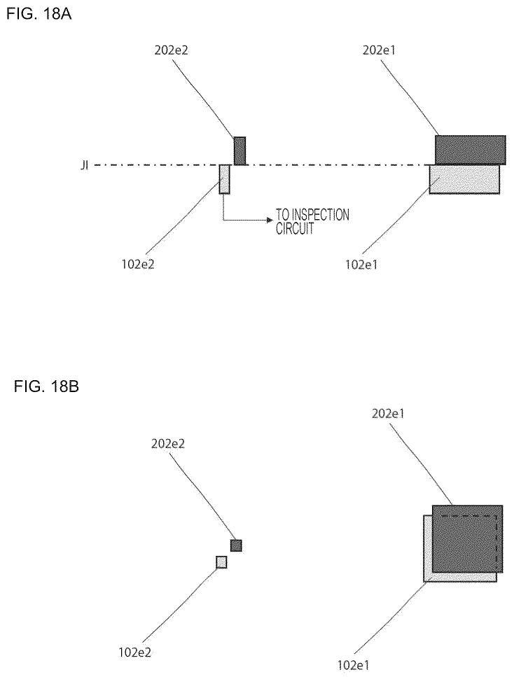

FIGS. 18A (cross-sectional view) and 18B (plan view) illustrate a state (case determined as fail) when the positional shift between the first and second connection terminals 102e1 and 202e1 has exceeded the predetermined value (for example, the allowable value) in the configuration example 4 of the positional shift detection system.

Here, the first and second connection terminals 102e1 and 202e1 for power line are designed to be relatively large (for example, about 120 μm) in order to allow a current to flow, but the first and second connection terminals 102e1 and 202e1 for signal line are designed to be relatively small (for example, about 60 μm) in order to reduce the chip size. The first and second connection terminals 102e1 and 202e1 for power line and for signal line are electrically connected if they are even slightly in contact with each other, and thus pass a functional test. Therefore, in the configuration example 4, as an example, a width W of the first and second electrodes 102e2 and 202e2 is set to be equal to or less than the allowable value of the positional shift of the first and second connection terminals 102e1 and 202e1, for example, a value (for example, 15 μm) obtained by multiplying the allowable value by α (safety factor).

For example, in the state illustrated in FIGS. 18A and 18B, the positional shift between the first and second connection terminals 102e1 and 202e1 exceeds the width W (for example, 15 μm), and the first and second electrodes 102e2 and 202e2 are in the non-contact state (electrically insulated state) with each other, while the first and second connection terminals 102e1 and 202e2 for power line and for signal line still have a sufficient contact area even if there is the positional shift, and conductivity is guaranteed in the future. In the state illustrated in FIGS. 18A and 18B, no current flows through the inspection circuit via the first electrode 102e2, so that it can be determined as fail.

### Configuration Example 5 of Positional Shift Detection System

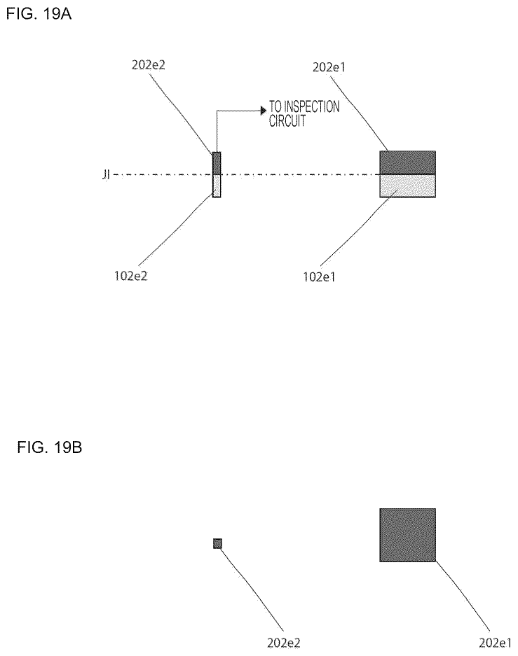

FIGS. 19A (cross-sectional view) and 19B (plan view) illustrate a state in which the positional shift of the first and second connection terminals 102e1 and 202e1 is equal to or less than a predetermined value (for example, an allowable value) (a state determined as pass) in a configuration example 5 of the positional shift detection system.

In the configuration example 5 of the positional shift detection system, an inspection circuit is provided in the second semiconductor structure 200, and the inspection circuit and the second electrode 202e2 are electrically connected.

The second semiconductor structure 200 has the same size as the size (for example, 300 mm) of the semiconductor substrate (wafer) before being divided into chips and can be inspected by an inspection circuit provided when it is in a substrate state, and only a passed product can be used. In a case of using such a second semiconductor structure 200, it is also possible to use the inspection circuit provided in the second semiconductor structure 200.

The first electrode 102e2 is connected to the power line inside the first semiconductor structure 200. For example, in the state illustrated in FIGS. 19A and 19B, since the second electrode 202e2 (inspection electrode) provided in the second semiconductor structure 200 is in contact with (is electrically connected to) the first electrode 102e2 (inspection electrode) provided in the first semiconductor structure 100, a voltage is applied. Therefore, a current flows through the inspection circuit via the second electrode 202e2. Therefore, when the current flows through the inspection circuit, it can be determined as pass. Note that a signal line in which some potential difference is generated may be used instead of the above-described power line.

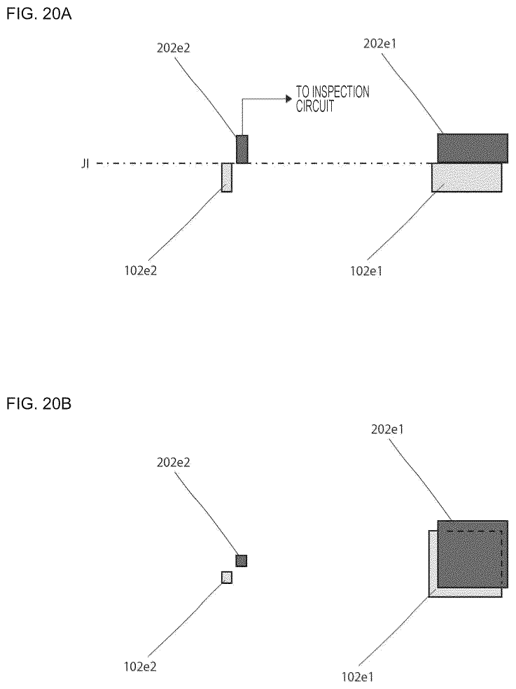

Meanwhile, in the state illustrated in FIGS. 20A and 20B, since the first and second electrodes 102e2 and 202e2 are in the non-contact state (electrically insulated state), no current flows through the inspection circuit via the second electrode 202e2. Therefore, when no current flows through the inspection circuit, it can be determined as fail.

### Configuration Example 6 of Positional Shift Detection System

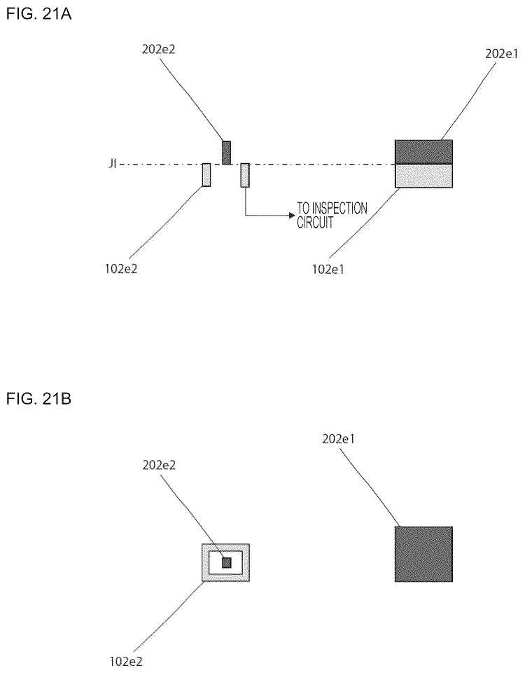

FIGS. 21A (cross-sectional view) and 21B (plan view) illustrate a state in which the positional shift of the first and second connection terminals 102e1 and 202e1 is equal to or less than a predetermined value (for example, an allowable value) (a state determined as pass) in a configuration example 6 of the positional shift detection system.

In the configuration example 6 of the positional shift detection system, the frame-shaped first electrode 102e2 is provided so as to surround the second electrode 202e2 in plan view, as illustrated in FIGS. 21A and 21B The clearance between the first and second electrodes 102e2 and 202e2 in plan view is the predetermined value (for example, 15 μm) equal to or less than the allowable value. In the state illustrated in FIGS. 21A and 21B, since the first and second electrodes 102e2 and 202e2 are in the non-contact state, no current flows through the inspection circuit provided in the first semiconductor structure 100. Therefore, when no current flows through the inspection circuit, it can be determined as pass.

Meanwhile, when the positional shift between the first and second connection terminals 102e1 and 202e1 exceeds the predetermined value, the first and second electrodes 102e2 and 202e2 are in a contact state with each other, and a current flows through the inspection circuit provided in the first semiconductor structure 100. Therefore, when the current flows through the inspection circuit, it can be determined as fail.

Note that a plurality of the first electrodes 102e2 may be provided so as to surround the second electrodes 202e2 in plan view. Furthermore, the frame-shaped second electrode 202e2 or a plurality of the second electrodes 202e2 may be provided so as to surround the first electrode 102e2 in plan view.

### Configuration Example 7 of Positional Shift Detection System

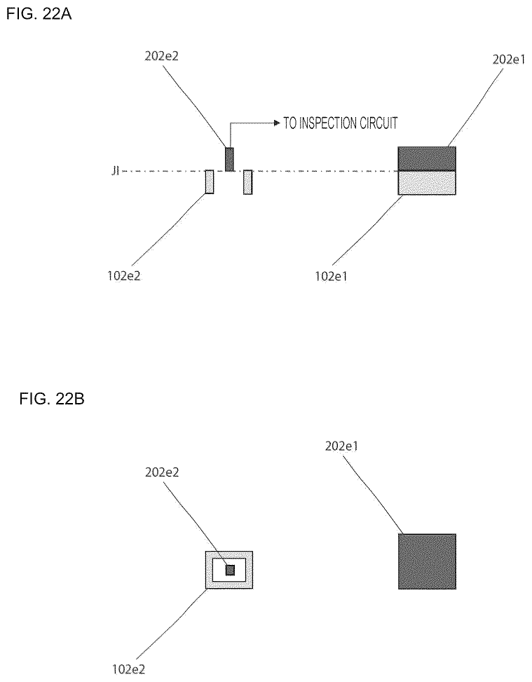

FIGS. 22A (cross-sectional view) and 22B (plan view) illustrate a state in which the positional shift of the first and second connection terminals 102e1 and 202e1 is equal to or less than a predetermined value (for example, an allowable value) (a state determined as pass) in a configuration example 7 of the positional shift detection system.

As illustrated in FIGS. 22A and 22B, the configuration example 7 of the positional shift detection system has a similar configuration to the configuration example 7 of the positional shift detection system except that the inspection circuit is provided in the second semiconductor structure 200.

### Configuration Example 8 of Positional Shift Detection System

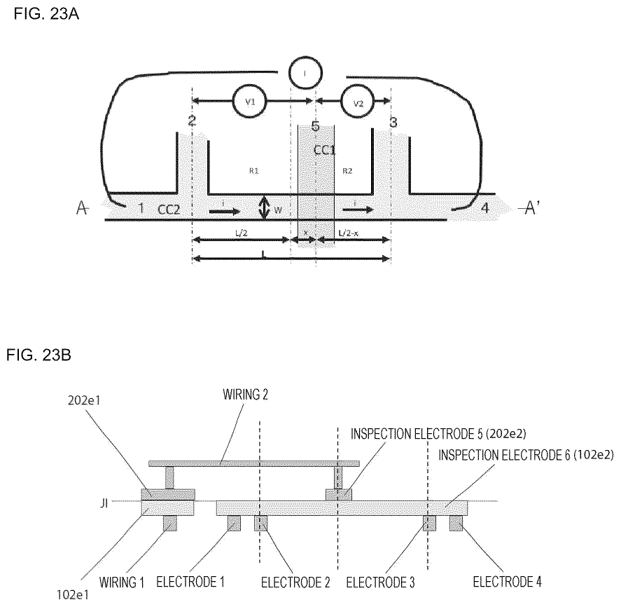

A configuration example 8 of the positional shift detection system has a configuration capable of detecting a positional shift amount and a positional shift direction of the first and second connection terminals, as illustrated in FIGS. 23A and 23B.

The positional shift detection system of the configuration example 8 is provided in a stacked structure in which the first and second semiconductor structures 100 and 200 are stacked and bonded, and electrically detects a positional relationship between the first and second electrodes 102e2 and 202e2 to detect the magnitude (positional shift amount) and/or the direction (positional shift direction) of the positional shift of the first and second connection terminals 102e1 and 202e1.

The configuration example 8 has a configuration that performs positional shift measurement to which Kelvin's theory is applied (a method that does not require sheet resistance).

The principle of the positional shift measurement at the time of bonding the first and second semiconductor structures 100 and 200 in the configuration example 8 will be described with reference to FIGS. 23A (plan view) and 23B (cross-sectional view). FIG. 23B is a cross-sectional view taken along line A-A′ of FIG. 23A.

The configuration of the positional shift measurement of the configuration example 8 will be described with reference to FIG. 23B. As illustrated in FIG. 23B, the first connection terminal 102e1 is connected to wiring 1 provided in the first semiconductor structure 100 and in which some potential difference is generated. The second connection terminal 202e1 is connected to an inspection electrode 5 (second electrode 202e2) via wiring 2. The inspection electrode 5 (also referred to as an electrode 5) is in contact with an inspection electrode 6 (first electrode 102e2) so as to be substantially orthogonal to the inspection electrode 6 in planar view. The inspection electrode 6 is connected to the inspection circuit via four electrodes 1, 2, 3, and 4 and internal wiring. Here, when a current is caused to flow between the electrodes 1 and 4 in a case where the inspection electrode 6 is in contact with the inspection electrode 5 at an intermediate position between the electrodes 2 and 3, the voltage between the electrodes 5 and 2 and the voltage between the electrodes 5 and 3 become equal. At this time, when the voltage between the electrodes 5 and 2 is substituted into V₁ of the following equation (2) and the voltage between the electrodes 5 and 3 is substituted into V₂, a calculation result of a positional shift amount x (the right side (electrode 3 side) is set to positive) becomes 0. Meanwhile, for example, when a center-to-center distance L between the electrodes 2 and 3 is 100 um, the voltage V₁ between the electrodes 5 and 2 is 0.2 V, and the voltage V₂ between the electrodes 5 and 3 is 0.15 V, the positional shift amount x is 7.1 um from the following equation (2). In a case where x is negative, it means that the inspection electrode 5 is shifted to the left side (electrode 2 side). In a case where the device can specify an offset of a stacking position when the second semiconductor structure 200 is stacked on the first semiconductor structure 100, it is possible to acquire an average value of a plurality of shift amounts and to finely adjust an offset amount by changing an offset amount from a next lot, thereby to improve a yield.

A procedure of the positional shift measurement of the configuration example 8 will be described with reference to FIG. 23A. As illustrated in FIG. 23A, first, the electrode 5 is laid out to be arranged between the electrodes 2 and 3 in plan view. As an example, when the electrode 5 is located between the electrode 2 and the electrode 3 in plan view, the positional shift between the first and second connection terminals 102e1 and 202e1 is 0. Next, a current i is caused to flow between the electrodes 1 and 4, and a voltage V1 between the electrodes 5 and 2 and a voltage V2 between the electrodes 5 and 3 are measured. At this time, when the positional shift is 0, V1=V2.

Here, it is assumed that the positional shift amount x is not 0. A resistance R₁ between the electrodes 2 and 5 is expressed by R₁=k (L/2+x)/W. A resistance R₂ between the electrodes 3 and 5 is expressed by R₂=k (L/2−x)/W. Note that k is the sheet resistance, L is the center-to-center distance between the electrodes 2 and 3, and W is the width of the inspection electrode 6.

Since the currents i flowing through R₁ and R₂ are equal, V1/R₁=V2/R₂. By substituting the expressions R₁ and R₂ into this equation, the following equation (1) is obtained. Furthermore, when the equation (1) is solved by x, the following equation (2) is obtained.

$${V}_{1} / ( L / 2 + x ) = {V}_{2} / ( L / 2 - x ) \qquad ( 1 )$$

$$x = ( {V}_{1} - {V}_{2} ) L / ( {V}_{1} + {V}_{2} ) 2 \qquad ( 2 )$$

In a case where x obtained from the above equation (2) is a positive value, it can be seen that the electrode 5 is shifted toward the electrode 3 side (right side) from the center of the electrodes 2 and 3 in plan view, and in a case where x is a negative value, the electrode 5 is shifted toward the electrode 2 side (left side) from the center of the electrodes 2 and 3 in plan view.

In the above-described principle of the measurement, since the width of the width W of the inspection electrode 6 and the sheet resistance are unnecessary, the positional shift amount and the positional shift direction can be measured only by measuring the voltage.

The detection of the positional shift amount and the positional shift direction in a y direction orthogonal to an x direction can be performed using a configuration obtained by rotating the configuration illustrated in FIGS. 23A and 23B by 90°.

### Configuration Example 9 of Positional Shift Detection System

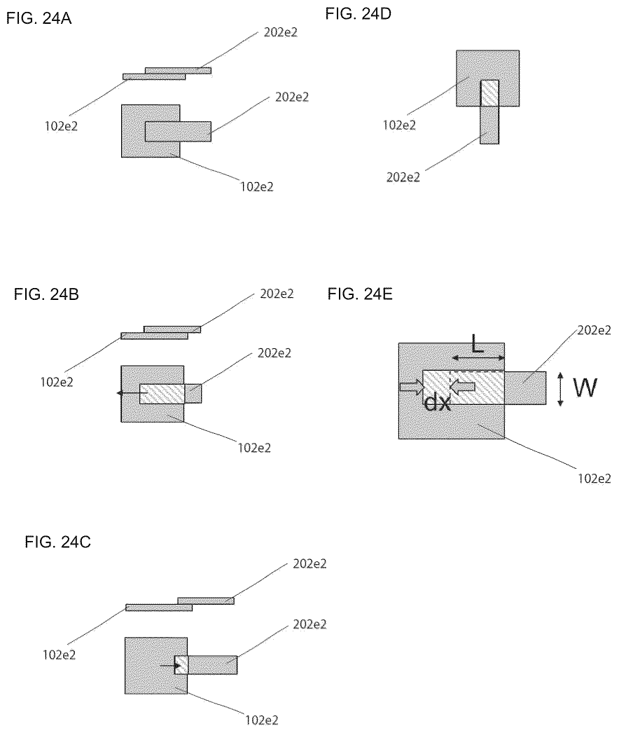

A configuration example 9 of the positional shift detection system has a configuration capable of detecting the positional shift amount and the positional shift direction of the first and second connection terminals, as illustrated in FIGS. 24A to 24E.

The positional shift detection system of the configuration example 9 is provided in a stacked structure in which the first and second semiconductor structures 100 and 200 are stacked and bonded, and electrically detects the positional relationship between the first and second electrodes 102e2 and 202e2 to detect the magnitude and/or the direction of the positional shift.

In the configuration example 9 of the positional shift detection system, the sizes of the first and second electrodes 102e2 and 202e2 are different and partially overlap. Here, the second electrode 202e2 is smaller than the first electrode 102e2.

For example, when the second semiconductor structure 200 is shifted in the arrow direction (left side) with respect to the first semiconductor structure 100, that is, in the direction in which an overlapping portion increases, as illustrated in FIG. 24B from the state illustrated in FIG. 24A (for example, from the state in which the positional shift of the first and second connection terminals is substantially 0), the contact area of the first and second electrodes 102e2 and 202e2 increases as indicated by the hatched portion. Therefore, since resistance value between the first and second electrodes 102e2 and 202e2 decreases, a large current flows when a voltage is applied between the first and second electrodes 102e2 and 202e2.

For example, when the second semiconductor structure 200 is shifted in the arrow direction (right side) with respect to the first semiconductor structure 100, that is, in the direction in which the overlapping portion decreases, as illustrated in FIG. 24C from the state illustrated in FIG. 24A, the contact area of the first and second electrodes 102e2 and 202e2 decreases as indicated by the hatched portion. Therefore, since the resistance value between the first and second electrodes 102e2 and 202e2 increases, a large current does not flow even if the same voltage as that in the example of FIG. 24B is applied.

Therefore, in the configuration example 9, the positional shift amount and the positional shift direction of the first and second connection terminals can be seen from the resistance value or a current value between the first and second electrodes 102e2 and 202e2.

Furthermore, it is possible to detect the positional shift amount and the positional shift direction in the direction (y direction) orthogonal to the direction of the positional shift (x direction) that can be detected in the example of FIG. 24A by preparing the first and second electrodes 102e2 and 202e2 having a layout obtained by rotating the layout of FIG. 24A by 90°, as illustrated in FIG. 24D.

The resistance R can be expressed as R=k (L+dX)/W, using W, L, and dX illustrated in FIG. 24E. Thus, dx=RW/k−L is obtained. Note that k=ρ/t [Ω], ρ: the electrical resistivity [Ω·m], and t: the thickness

It is possible to know the relationship between the resistance value and the positional shift amount by acquiring the resistance value of a sample whose positional shift amount has been measured from an outer shape in advance, as a method of converting the resistance value into the positional shift amount. Therefore, when the resistance value is known, the resistance value can be converted into the positional shift amount. Alternatively, the resistance value may be extracted from layout information and calculated, using a function of CAD software, or may be calculated from resistivity or dimensions of a material.

### Configuration Example 10 of Positional Shift Detection System

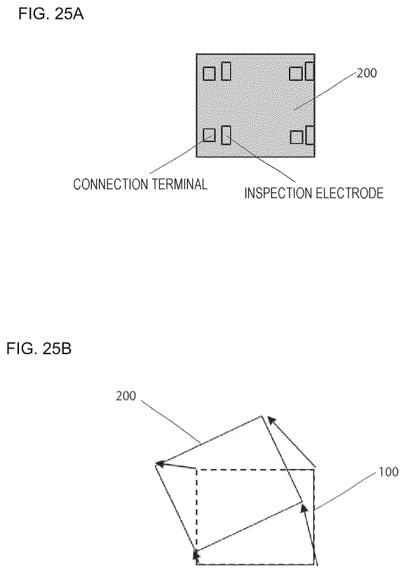

A configuration example 10 of the positional shift detection system has a configuration capable of detecting the positional shift amounts and the positional shift directions of the first and second connection terminals in xy directions and a rotation direction around a z axis (an axis orthogonal to both the x axis and the y axis), as illustrated in FIGS. 25A and 25B.

In the configuration example 10, as an example, connection terminals and inspection electrodes are provided at four corners of each of the first and second semiconductor structures 100 and 200. This makes it possible to accurately detect the positional shift amount and the positional shift direction of the first and second connection terminals in the xy directions and the rotation direction around the z axis.

### Configuration Example 11 of Positional Shift Detection System

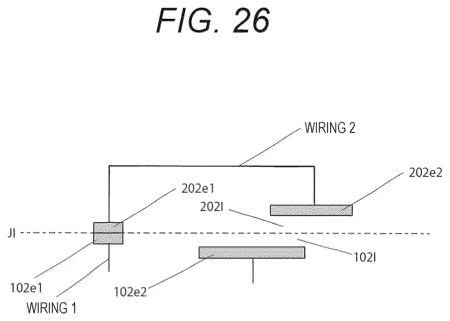

In a configuration example 11 of the positional shift detection system, the first and second electrodes 102e2 and 202e2 are disposed at positions where the capacitance between the first and second electrodes 102e2 and 202e2 is changeable according to the positional shift of the first and second connection terminals 102e1 and 202e1, as illustrated in FIG. 26.

In the configuration example 11, the first and second electrodes 102e2 and 202e2 face each other with the insulating films 102I and 202I interposed therebetween.

In the configuration example 11, it is possible to detect the positional shift amount and the positional shift direction of the first and second connection terminals 102e1 and 202e1 by a change in the capacitance between the first and second electrodes 102e2 and 202e2.

### Configuration Example 12 of Positional Shift Detection System

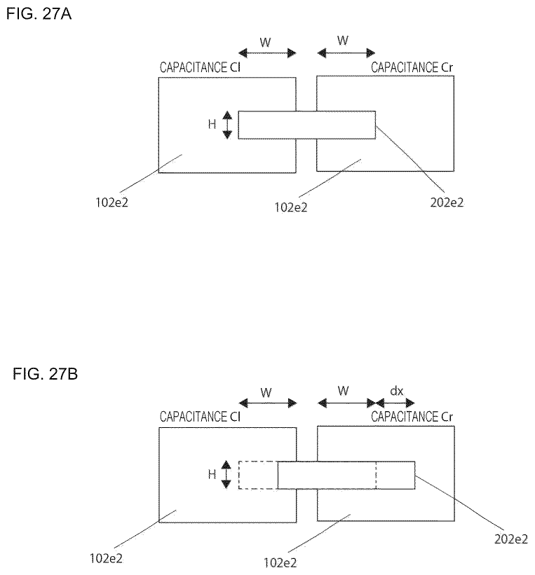

In a configuration example 12 of the positional shift detection system, the first and second electrodes 102e2 and 202e2 are disposed at positions where the capacitance between the first and second electrodes 102e2 and 202e2 is changeable according to the positional shift of the first and second connection terminals, as illustrated in FIGS. 27A and 27B.

In the configuration example 12, the second electrode 202e2 is disposed via an insulating film to straddle the two first electrodes 102e2 arranged at a predetermined interval.

The first electrode 102e2 on one side (left side) and the second electrode 202e2 constitute a capacitance Cl, and the first electrode 102e2 on the other side (right side) and the second electrode 202e2 constitute a capacitance Cr.

For example, in the state illustrated in FIG. 27A, that is, when Cl=Cr, the positional shift between the first and second connection terminals is 0.

Meanwhile, for example, in the state illustrated in FIG. 27B, the second semiconductor structure 200 is positionally shifted by dx with respect to the first semiconductor structure 100. At this time, a sum of areas of facing portions of the capacitances Cl and Cr is 2WH, and an area difference is 2d×H. At this time, a ratio between the difference and the sum of Cl and Cr becomes (k×2d×H)/(k×2WH)=dx/W. Therefore, (Cr−Cl)/(Cr+Cl)=dx/W is established. Solving the equation for dx yields dx=(Cr−Cl)/(Cr+Cl)×W. The positional shift in the y direction orthogonal to the x direction can be similarly obtained.

### Configuration Example 13 of Positional Shift Detection System

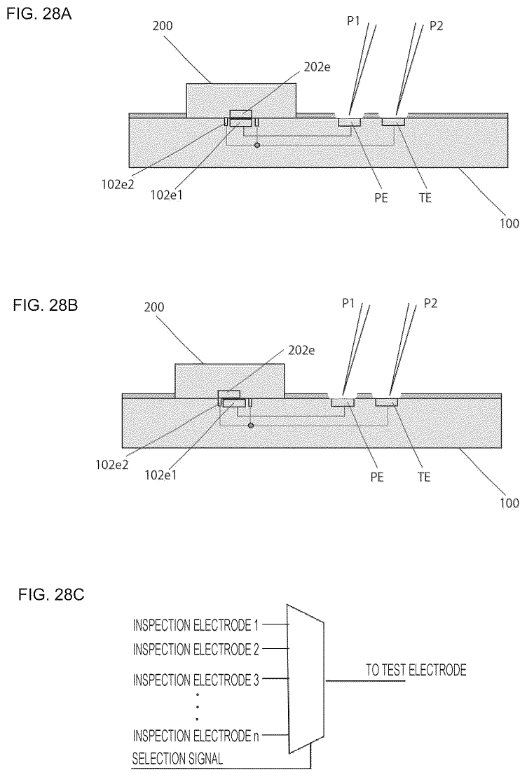

In a configuration example 13 of the positional shift detection system, as an example, the first electrode 102e2 is provided in first semiconductor structure 100 so as to surround the first connection terminal 102e1, as illustrated in FIGS. 28A and 28B. The first connection terminal 102e1 is connected to a power supply electrode PE provided to be exposed to a surface of the first semiconductor structure 100 via the internal wiring of the first semiconductor structure 100. The first electrode 102e2 is connected to a test electrode TE provided to be exposed to the surface of the first semiconductor structure 100 via the internal wiring of the first semiconductor structure 100.

Probes P1 and P2 connected to the inspection device are brought into contact with the power supply electrode PE and the test electrode TE, respectively, and conduction/non-conduction is examined, whereby the pass/fail determination can be performed. For example, in the state illustrated in FIG. 28A, since the first electrode 102e2 and the second connection terminal 202e are not in contact with each other, no current flows between the probes P1 and P2, and it can be determined as pass. For example, in the state illustrated in FIG. 28B, since the first electrode 102e2 and the second connection terminal 202e are in contact with each other, a current flows between the probes P1 and P2, and it can be determined as fail. In a case where a plurality of the first electrodes 102e2 as inspection electrodes is arranged, the same number of test electrodes may be provided, but there is a possibility that the test electrodes do not fit within the chip size, and efficiency is not good. Therefore, there is a method of using a selection circuit (for example, a multiplexer or the like) as illustrated in FIG. 28C. In this method, a selection signal is transmitted to one test electrode, and inspection electrodes (for example, inspection electrodes 1 to n) connected to the test electrode can be switched. By providing such a selection circuit, installation of the test electrode can be suppressed to the minimum installation.

### (Details of Inspection Circuit)

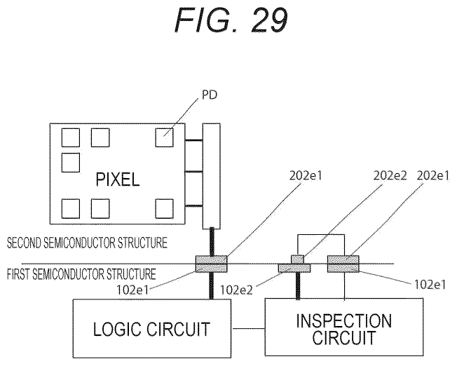

As illustrated in FIG. 29, the inspection circuit described above includes a normal inspection circuit (former) that determines whether or not the photoelectric conversion element (for example, PD) and the logic circuit normally operate, and a positional shift inspection circuit (latter) that inspects the positional shift of the first and second connection terminals. The former and the latter are configured as the same testing circuit in the example of FIG. 29, but may be configured as different inspection circuits.

### (Example Using Interface of JTAG Standard)

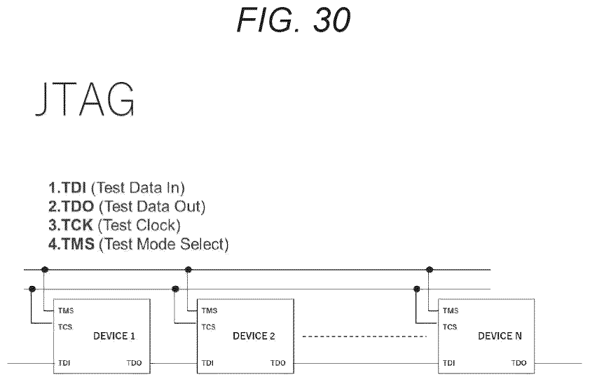

In the above description, the unique inspection circuit has been described, but for example, an interface of IEEE1149.1 standardized by Joint Test Action Group (JTAG) may be used. As illustrated in FIG. 30, this standard includes only at least four signal lines, and operates only by chain-connecting a plurality of devices. Each device has an ID (contact address) to be in charge, and sends an address to operate to a test mode select (TMS) by serial communication. When the IDs match, each device operates and outputs a test result to a test data out (TDO). The device having an unmatched ID outputs data received from a test data in (TDI) terminal to the TDO as it is. This method only needs to sequentially transfer data. Each device may have one inspection circuit or a plurality of testing circuits.

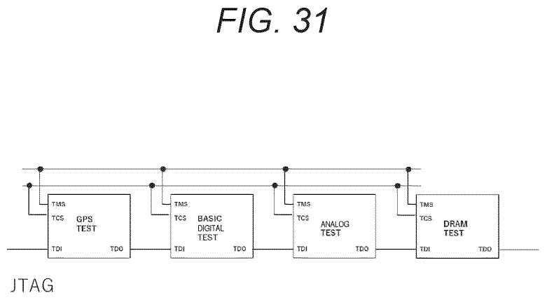

A device group including a plurality of devices may be provided in the first semiconductor structure and/or the second semiconductor structure. For example, in a semiconductor device including a first semiconductor structure in which a digital circuit and an analog circuit are provided, and a second semiconductor structure in which a GPS circuit is provided, and a second semiconductor structure in which a DRAM circuit is provided, the semiconductor device can be regarded as a simply chain-connected circuit without having to be conscious of the first semiconductor structure and the second semiconductor structure, as illustrated in FIG. 31. For example, in a case of testing the DRAM, when an ID and a command for operating the DRAM are transmitted as a set, a TEST block of the DRAM operates and transmits a result. During the inspection of the DRAM, another TEST circuit only repeats outputting data received from the TDI to the TDO.

### (Example of Having Positional Shift Inspection Circuit Incorporated in Analog TEST Device Group)

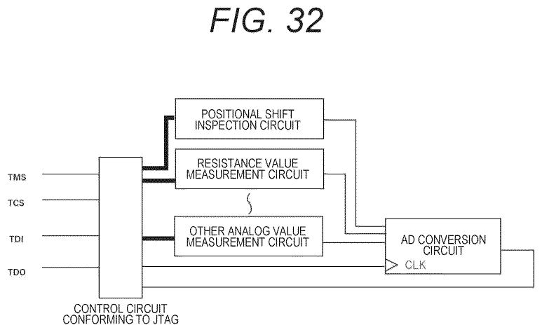

FIG. 32 illustrates an example in which the positional shift inspection circuit is one analog TEST device included in an analog TEST device group. Here, a control circuit conforming to JTAG is required. The control circuit has functions of a decoding circuit for decoding an ID, a circuit for selecting an inspection circuit corresponding to a decoded signal, an encoding circuit for generating an output code to be output, and a buffer circuit for receiving and transmitting input data. As one of various analog TEST devices, the positional shift inspection circuit is incorporated. Signal lines from a plurality of inspection electrodes are connected to the positional shift inspection circuit. The control circuit selectively selects the signal line from the plurality of inspection electrodes and performs measurement. An analog value that is a measurement result is converted into digital data by an AD conversion circuit, and the digital data is encoded and output to the TDO. As described above, the positional shift inspection circuit can be incorporated in the analog TEST device group conforming to JTAG. Note that the example illustrated here is an example, and there may be a plurality of the TEST device groups, or the TEST device group may be constituted only by the positional shift inspection circuits. Another circuit may be added as long as the configuration of the control circuit conforms to the JTAG standard.

### (Example of Connecting Positional Shift Detection System That Is in Open State When Determined as Pass and in Short-circuit State When Determined as Fail to Positional Shift Inspection Circuit Provided in First Semiconductor Structure)

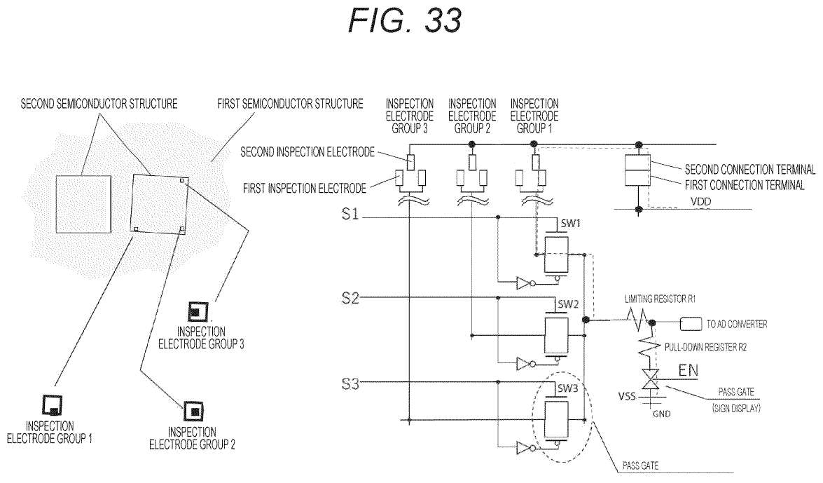

The left diagram of FIG. 33 is a plan view schematically illustrating a semiconductor device including a positional shift detection system including an inspection electrode group including an inspection electrode (also referred to as a first inspection electrode) provided in the first semiconductor structure 100 and an inspection electrode (also referred to as a second inspection electrode) provided in the second semiconductor structure 200. In the positional shift detection system, the first inspection electrode is disposed so as to surround the second inspection electrode in plan view (see the right diagram in FIG. 33). The first and second inspection electrodes are electrically insulated when the positional shift when the first and second semiconductor structures 100 and 200 are bonded is equal to or less than an allowable value, and the first and second inspection electrodes are electrically connected when the positional shift exceeds the allowable value.

When the first and second inspection electrodes (corresponding two inspection electrodes) are collectively referred to as an inspection electrode group, inspection electrode groups 1, 2, and 3 are arranged at positions corresponding to three corners of the second semiconductor structure 200 (see the left diagram of FIG. 33). In the state illustrated in FIG. 33, the first inspection electrode and the second inspection electrode of the inspection electrode group 1 are electrically connected among the inspection electrode group 1, the inspection electrode group 2, and the inspection electrode group 3 (see the right diagram in FIG. 33).

In the positional shift inspection circuit, the above-described control circuit conforming to JTAG and switches SW1, SW2, and SW3 are connected via signal lines S1, S2, and S3, respectively. Each of the switches SW1, SW2, and SW3 is a pass gate including a PMOS and an NMOS, and can turn on and off an analog value as it is. An output terminal of each switch is connected to GND via a limiting resistor R1, a pull-down resistor R2, and a pass gate in this order. A connection point of the limiting resistor R1 and the pull-down resistor R2 is connected to an AD converter.

When receiving an operation command, the control circuit sequentially transmits an ON signal to the corresponding switches SW1, SW2, and SW3 via S1, S2, and S3, and sequentially checks the connection from the inspection electrode group 1 to the inspection electrode group 3. At this time, the analog value from each inspection electrode group is sequentially output via the corresponding switch.

When the positional shift inspection circuit is on standby, S1, S2, and S3 are turned off, and an EN signal is also turned off, so that no voltage is input to the AD converter. When the positional shift inspection circuit is in operation, EN is turned on, and S1, S2, and S3 are sequentially turned on.

First, when S1 is turned on, the first and second inspection electrodes of the inspection electrode group 1 are electrically connected as described above, and thus a current flows to VSS via VDD. At this time, the voltage divided by R1 and R2 is input to the AD converter. Next, when S2 is turned on, the first and second inspection electrodes of the inspection electrode group 2 are electrically insulated, and thus no current flows. Since the EN signal is on, a VSS voltage is output to the AD converter via R2. Next, even when S3 is turned on, the first and second inspection electrodes of the inspection electrode group 3 are electrically insulated, and thus the VSS voltage is input to the AD converter.

The AD converter converts the input voltage into a digital value. This digital value is converted into serial data by the control circuit conforming to JTAG. At this time, in the control circuit, for example, a code of 0 V to 0.001 V is output as pass as serial data, and a code of the other voltage is output as NG (fail) as serial data. Note that, in a case where a contact resistance between the inspection electrodes is significantly higher than the resistance value of the pull-down resistor R2, the output voltage is considerably low. Therefore, it is desirable to perform a test in advance and determine a determination voltage.

### (Example of Obtaining Positional Shift Amount and Positional Shift Direction By Change in Resistance Value)

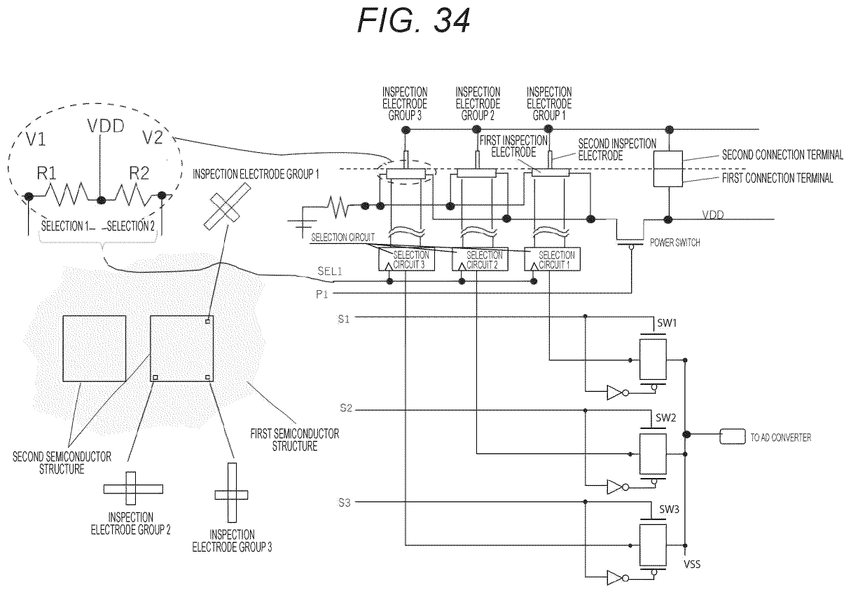

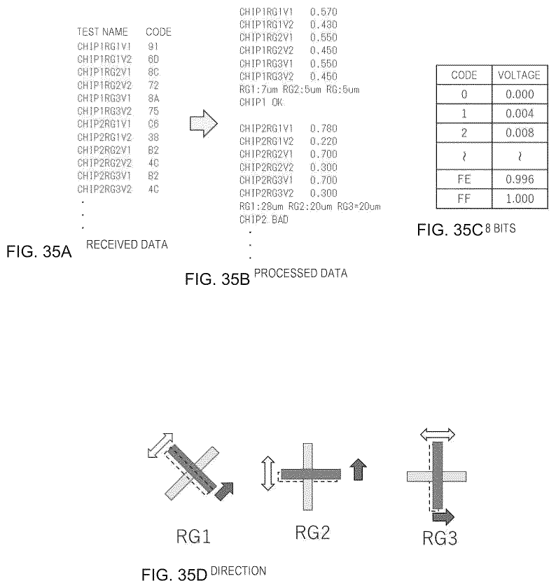

Hereinafter, an example of connecting the configuration example 8 (see FIGS. 23A and 23B) of the positional shift detection system is connected to the positional shift inspection circuit will be described with reference to FIGS. 34 and 35.

In the configuration example 8, as illustrated in FIG. 34, the first and second inspection electrodes of each inspection electrode group are arranged to be substantially orthogonal to each other in plan view, and the values of the resistor R1 and the resistor R2 are changed according to the positional shift of the first and second connection terminals.

In the positional shift inspection circuit, the above-described control circuit conforming to JTAG and switches SW1, SW2, and SW3 are connected via signal lines S1, S2, and S3, respectively. Each of the switches SW1, SW2, and SW3 is a pass gate including a PMOS and an NMOS, and can turn on and off an analog value as it is. The output terminal of each switch is connected to the AD converter.

Here, since the control circuit conforming to JTAG receives the operation command and the two resistors R1 and R2 are connected to each inspection electrode group, and thus a selection signal SEL1 for determining which resistor is to be measured is input to the selection circuit. Here, when SEL1 is HI, the resistor R1 of selection 1 is selected, and when SEL1 is LOW, the resistor R2 of selection 2 is selected. The resistance value of the selected resistor is input to the AD converter via the pass gate.

Furthermore, since the control circuit calculates the resistance value by causing the current to flow and measuring the voltage in Kelvin measurement, a signal line for transmitting an ON signal P1 of a power switch is provided in order to prevent the current from flowing when the positional shift inspection circuit is stopped. Here, since the PMOS is used as a switch, P1 is set to LOW when the PMOS is operated, and is set to HI when the PMOS is stopped. Serial data is output by the AD converter and the control circuit.

FIG. 35 illustrates an example of actual test results. In this example, a test name and a code as the test result are received as text data (the upper left diagram (a) of FIG. 35). Here, the measurement is performed at 1 V. Furthermore, since AD conversion is divided from 0 to FF, one bit corresponds to 0.004 V (the upper right diagram (c) of FIG. 35). Therefore, the received code can be analyzed and determined by a general computer or the like. 91 in hexadecimal digits is 0.57 V, and 6D is 0.43 V. At this time, since L/2 is 50 μm if design is made with L=100 μm, a positional shift amount is obtained by dividing a voltage difference by a sum of voltages and applying half of L. Therefore, a positional shift amount RG1 of the inspection electrode group 1 of a CHIP1 is (0.57−0.43)/(0.57+0.43)×50=7 um. This is a positive value, which means that the selection circuit is shifted in the direction of the dark arrow in the lower diagram (d) of FIG. 35 in a case where the selection circuit is operated from a direction of a selection circuit 1 according to a theoretical formula. When the positional shift amount is a negative value, the selection circuit is shifted in an opposite direction. For example, in a case where the positional shift amounts are determined pass when within 20 μm, in the case of CHIP1, all of positional shift amounts RG1, RG2, and RG3 of the inspection electrode groups 1, 2, and 3 are determined as pass (the upper center diagram (b) of FIG. 35). Subsequently, in the case of CHIP2, since RG1 exceeds 20 um, it is determined as fail even if RG2 and RG3 are determined as pass. Since the positional shift amount is obtained as a numerical value in this manner, in a case where a device on which a chip is mounted has a mechanism capable of adjusting an offset amount when the chip is mounted, it is possible to improve a yield by adjusting the offset amount in units of several lots or the like. Therefore, it is possible to reduce a factor of a constant error caused by a slight temperature variation or the like due to a lapse of time in one day, a change in season, or the like.

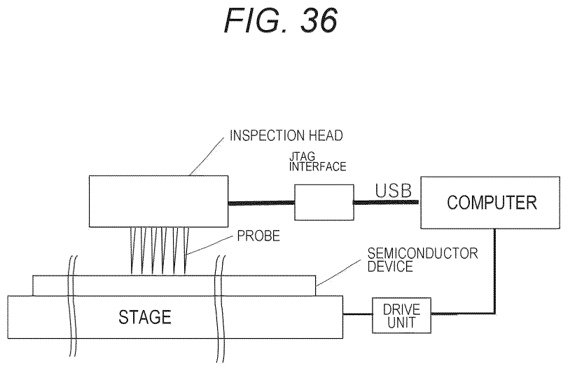

FIG. 36 illustrates a configuration example of an inspection system using probes (see FIGS. 28A and 28B). In the example of FIG. 36, the semiconductor device is mounted on a stage movable in a horizontal direction by a drive unit. An inspection head including a plurality of probes is disposed above the semiconductor device. In the inspection head, a computer is connected to the normal inspection circuit and the positional shift inspection circuit via a JTAG interface and a USB cable. When inspection of one portion of the semiconductor device by the inspection head is completed, the computer moves the stage in the horizontal direction to inspect the next portion. When inspection of all the inspection portions by the inspection head is completed, the computer determines the pass/fail of the positional shift of the first and second semiconductor structures.

### (Method of Bonding First and Second Semiconductor Structures)

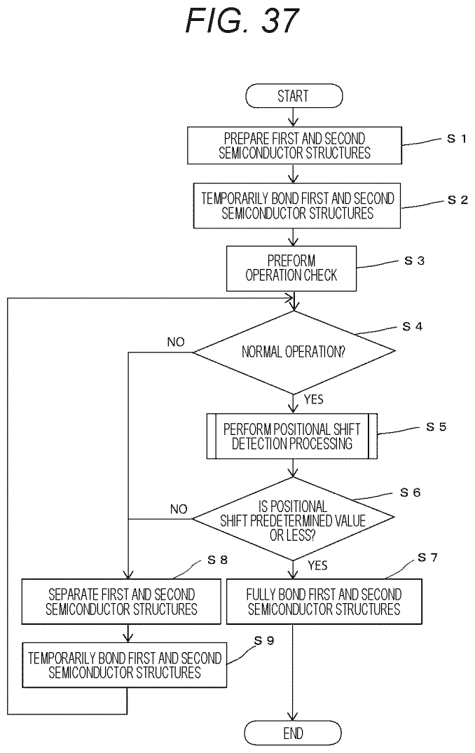

Hereinafter, an example of a method of bonding the first and second semiconductor structures performed at the time of manufacturing the semiconductor device 10 will be described with reference to the flowchart in FIG. 37.

In the first step S1, the first and second semiconductor structures 100 and 200 are prepared. Specifically, the first semiconductor structure 100 is produced by forming a photoelectric conversion element on the first semiconductor substrate 101 and forming the first wiring layer 102 on the first semiconductor substrate 101 by photolithography. The second semiconductor substrate 201 is formed by forming a processing circuit (for example, a logic circuit and a memory circuit) for each chip on a wafer to be the second semiconductor substrate 201 by photolithography, forming a wiring film to be the second wiring layer 202 on the wafer, and then separating the wafer for each chip by dicing.

In next step S2, the first and second semiconductor structures 100 and 200 are temporarily bonded. Specifically, first, the second semiconductor structure 200 held by a manipulator is aligned in the horizontal direction above the first semiconductor structure 100 held on the stage. Next, the second semiconductor structure 200 held by the manipulator is lowered toward the first semiconductor structure 100 under predetermined temperature and pressure conditions, thereby temporarily bonding the first and second semiconductor structures 100 and 200.

In next step S3, operation check is performed. Specifically, operation check of the photoelectric conversion element and the processing circuit is performed using the normal inspection circuit provided in the first semiconductor structure 100 and/or the second semiconductor structure 200.

In next step S4, it is determined whether or not the operation has been normally performed. Specifically, it is determined whether or not the photoelectric conversion element and the processing circuit normally operate on the basis of the inspection result from the normal inspection circuit. When the determination here is positive, the processing proceeds to step S5, and when the determination is negative, the processing proceeds to step S8.

In step S5, positional shift detection processing is performed. The positional shift detection processing is performed by the positional shift inspection circuit. Details of the positional shift detection processing will be described below.

In next step S6, it is determined whether or not the positional shift is a predetermined value (for example, an allowable value) or less. Specifically, it is determined whether or not the positional shift of the first and second connection terminals is a predetermined value or less on the basis of the inspection result (for example, pass/fail determination, positional shift amount, or the like) of each inspection electrode or each inspection electrode group from the positional shift inspection circuit. The processing proceeds to step S7 when the determination in step S6 is positive, and proceeds to step S8 when the determination is negative.

In step S7, the first and second semiconductor structures 100 and 200 are fully bonded. Specifically, processing for permanent bonding is performed for bonding portions of the first and second semiconductor structures 100 and 200. When step S7 is executed, the flow is terminated.

In step S8, the first and second semiconductor structures 100 and 200 are separated. Specifically, the temporary bonding of the first and second semiconductor structures 100 and 200 is released by holding the second semiconductor structure 200 with a manipulator and raising the second semiconductor structure 200 so as to be separated from the first semiconductor structure 100 under predetermined temperature and pressure conditions.

In step S9, the first and second semiconductor structures 100 and 200 are temporarily bonded. Specifically, first, the second semiconductor structure 200 held by a manipulator is aligned in the horizontal direction above the first semiconductor structure 100 held on the stage. At this time, alignment accuracy can be improved by feeding back the positional shift amount and the positional shift direction from the positional shift inspection circuit and controlling the manipulator. Next, the second semiconductor structure 200 held by the manipulator is lowered toward the first semiconductor structure 100 under predetermined temperature and pressure conditions, thereby temporarily bonding the first and second semiconductor structures 100 and 200. In a case where step S9 is performed, the processing returns to step S4.

### (Positional Shift Detection Processing)

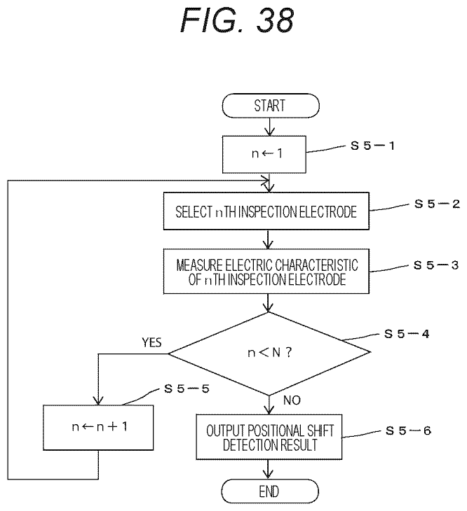

Hereinafter, the positional shift detection processing (step S5 in FIG. 37) will be described with reference to the flowchart in FIG. 38. The positional shift detection processing is performed by the positional shift inspection circuit.

In first step S5-1, n is set to 1.

In next step S5-2, the nth inspection electrode (or the nth inspection electrode group) is selected.

In next step S5-3, an electrical characteristic of the nth inspection electrode (or the nth inspection electrode group) is measured. Specifically, the positional shift inspection circuit measures a conduction/non-conduction state between the nth inspection electrode and the corresponding connection terminal, or a conduction/non-conduction state between the first and second inspection electrodes or a change state of capacitance of the nth inspection electrode group.

In next step S5-4, it is determined whether or not n<N (N is a total number of inspection electrodes or inspection electrode groups). When the determination here is positive, the processing proceeds to step S5-5, and when the determination is negative, the processing proceeds to step S5-6.

In step S5-5, n is incremented.

In step S5-6, a positional shift detection result is output. Specifically, measurement results in step S5-3 for all the inspection electrodes or the inspection electrode groups are output.

### 2. Modifications of Present Technology

### (Semiconductor Device of Modification 1 of Present Technology)

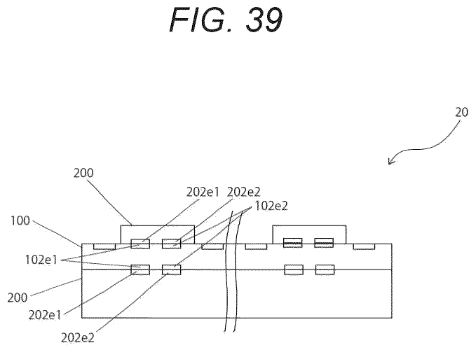

FIG. 39 is a cross-sectional configuration view of a semiconductor device 20 according to a modification 1 of the present technology. The semiconductor device 20 has a stacked structure in which a plurality of (for example, three layers of) semiconductor structures is stacked. In the semiconductor device 20, as an example, a plurality of chip-shaped second semiconductor structures 200 (uppermost layer) is bonded to the front surface of a wafer-sized first semiconductor structure 100 (intermediate layer), and a second semiconductor structure 200 (lowermost layer) having the same size (wafer size) as the first semiconductor structure 100 is bonded to the back surface of the first semiconductor structure 100. Also in the semiconductor device 20, it is possible to inspect the positional shift of the first and second connection terminals 100e1 and 200e1 at each bonding, similarly to the semiconductor device 10.

### (Semiconductor Device of Modification 2 of Present Technology)

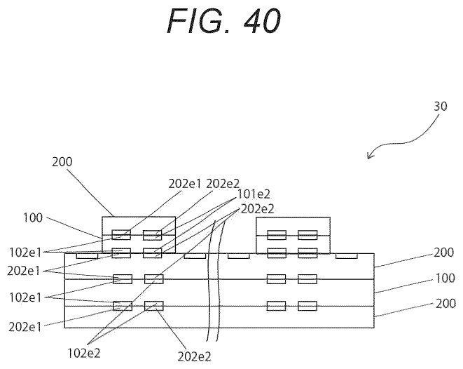

FIG. 40 is a cross-sectional configuration view of a semiconductor device 30 according to a modification 2 of the present technology. The semiconductor device 30 has a stacked structure in which a plurality of (for example, five layers of) semiconductor structures is stacked. In the semiconductor device 30, as an example, a wafer-sized first semiconductor structure 100 is bonded to the surface of a wafer-sized second semiconductor structure 200 (lowermost layer), a wafer-sized second semiconductor structure 200 is bonded to the surface of the first semiconductor structure 100, a plurality of chip-shaped first semiconductor structures 100 is bonded to the surface of the second semiconductor structure 200, and a chip-shaped second semiconductor structure 200 (uppermost layer) is bonded to the surface of each chip-shaped first semiconductor structure 100. Also in the semiconductor device 30, it is possible to inspect the positional shift of the first and second connection terminals 100e1 and 200e1 at each bonding, similarly to the semiconductor device 10.

### (Semiconductor Device of Modification 3 of Present Technology)

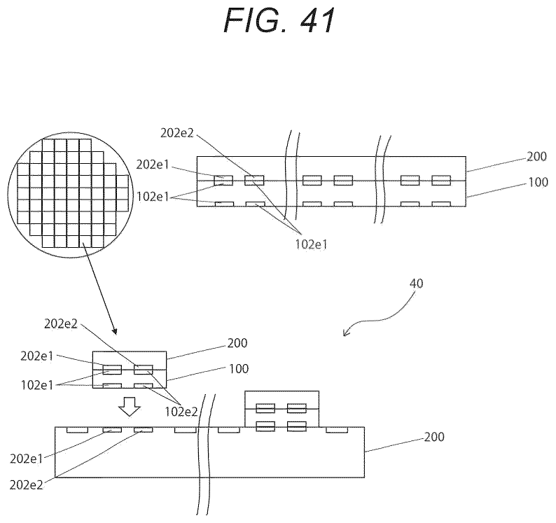

FIG. 41 is a cross-sectional configuration view of a semiconductor device 40 according to a modification 3 of the present technology. The semiconductor device 40 has a stacked structure in which a plurality of (for example, three layers of) semiconductor structures is stacked. A method of manufacturing the semiconductor device 40 will be briefly described. First, a wafer-sized second semiconductor structure 200 is bonded to the surface of a wafer-sized first semiconductor structure 100. Next, this two-layer structure is separated into a plurality of chips by dicing, and the plurality of chips is bonded to the surface of the wafer-sized second semiconductor structure 200. Also in the semiconductor device 40, it is possible to inspect the positional shift of the first and second connection terminals 100e1 and 200e1 at each bonding, similarly to the semiconductor device 10.

### (Semiconductor Device of Modification 4 of Present Technology)

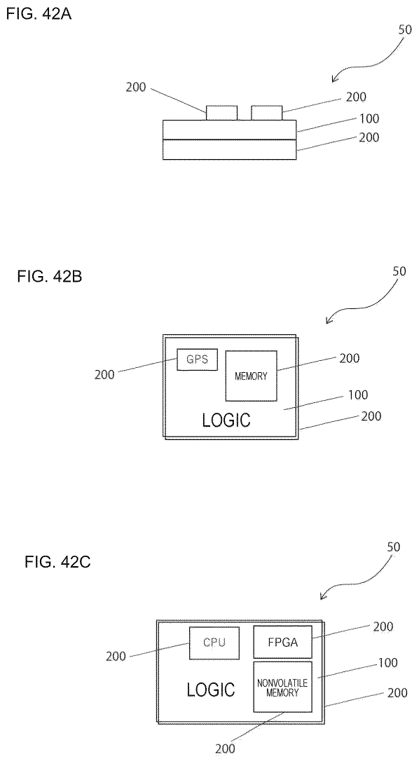

FIG. 42A is a view schematically illustrating a cross-sectional configuration of a semiconductor device 50 according to a modification 4 of the present technology. FIGS. 42B and 42C are views illustrating a planar configuration example of the semiconductor device 50 according to the modification 4 of the present technology.

The semiconductor device 50 has a stacked structure in which a plurality of (for example, three layers of) semiconductor structures is stacked, as illustrated in FIG. 42A. In the semiconductor device 50, as an example, a wafer-sized first semiconductor structure 100 (intermediate layer) is bonded to the surface of a wafer-sized second semiconductor structure 200 (lowermost layer), and a plurality of chip-shaped second semiconductor structures 200 (uppermost layer) is bonded to the surface of the first semiconductor structure 100.

In the semiconductor device 50, as an example, as illustrated in FIG. 42B, the second semiconductor structure 200 as the lowermost layer can be a pixel substrate, the first semiconductor structure 100 as the intermediate layer can be a logic substrate, one of the two second semiconductor structures 200 as the uppermost layer can be a GPS chip, and the other can be a memory chip. Note that a combination of the chips constituting the plurality of chip-shaped second semiconductor structures 200 can be appropriately changed.

In the semiconductor device 50, as an example, as illustrated in FIG. 42C, the second semiconductor structure 200 as the lowermost layer can be a pixel substrate, the first semiconductor structure 100 as the intermediate layer can be a logic substrate, and the three second semiconductor structures 200 as the uppermost layer can be a CPU chip, an FPGA chip, and a nonvolatile memory chip, respectively. Note that a combination of the chips constituting the plurality of chip-shaped second semiconductor structures 200 can be appropriately changed.

### (Method of Manufacturing Semiconductor Device Having Three-layer Structure)

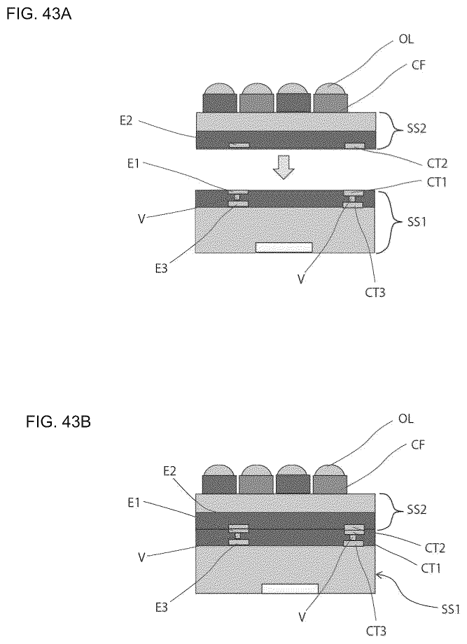

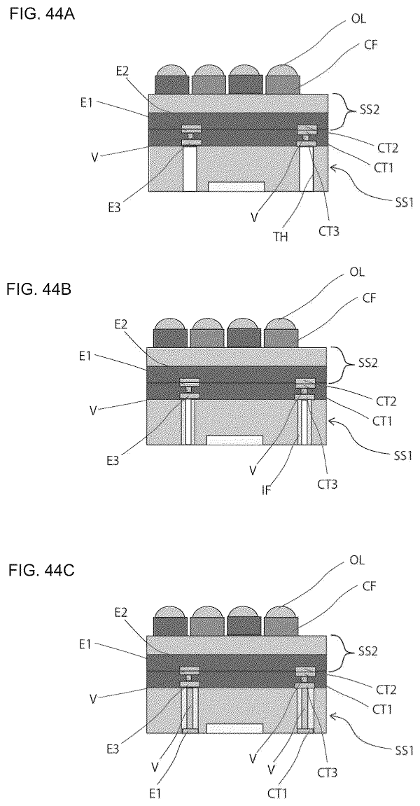

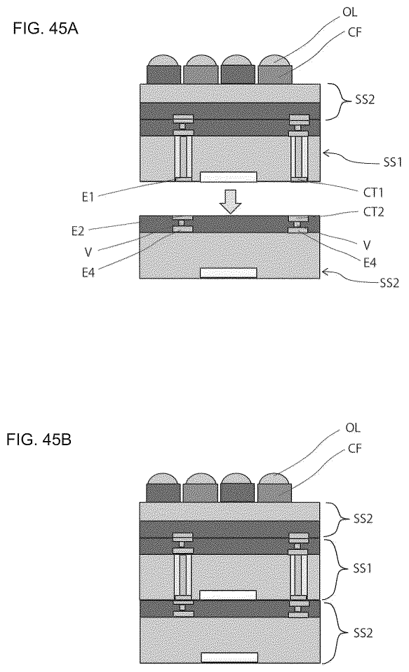

Hereinafter, an example of a method of manufacturing the semiconductor device having a three-layer structure (the semiconductor device 2 of the configuration example 2 described above) will be briefly described with reference to FIGS. 43A to 45B.
(process 1) The second semiconductor structure SS2 in which the color filter CF and the on-chip lens OL are formed and the first semiconductor structure SS1 are bonded (see FIG. 43A).
(process 2) The positional shift detection processing (see FIG. 38) is performed (see FIG. 43B).
(process 3) A through hole TH is formed in the back surface of the first semiconductor structure SS1 (see FIG. 44A).
(process 4) After an insulating film IF is formed in the through hole TH, a part of the insulating film IF is etched to expose the third connection terminal CT3 (see FIG. 44B).
(process 5) A via having one end in contact with the third connection terminal CT3 is formed inside the insulating film IF, and a land to serve as the first connection terminal CT1 is formed at the other end of the via (see FIG. 44C).
(process 6) The first semiconductor structure SS1 having the stacked structure including the second semiconductor structure SS2 serving as an upper layer and the first semiconductor structure SS1 serving as the intermediate layer, and the second semiconductor structure SS2 serving as the lower layer, which are generated in process 5, are bonded (see FIG. 45A).
(process 7) The positional shift detection processing (see FIG. 38) is performed (see FIG. 45B).

### (Semiconductor Devices of Modifications 5 to 7 of Present Technology)

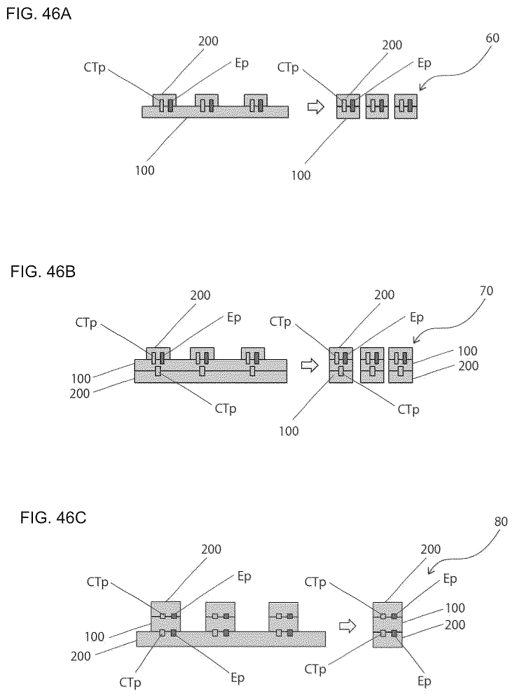

FIGS. 46A to 46C are views respectively schematically illustrating cross-sectional configurations of semiconductor devices according to modifications 5 to 7 of the present technology.

As illustrated in FIG. 46A, a semiconductor device 60 of the modification 5 has a stacked structure (for example, a two-layer structure) in which chip-shaped first and second semiconductor structures 100 and 200 are bonded. An example of a method of manufacturing the semiconductor device 60 of the modification 5 will be briefly described. First, a wafer-sized first semiconductor structure 100 (lower layer) and a plurality of chip-shaped second semiconductor structures 200 (upper layer) are bonded. After bonding, the positional shift of a connection terminal pair CTp is inspected using an inspection electrode pair Ep, and after the inspection is passed, the two-layer structure is separated into chips.

As illustrated in FIG. 46B, a semiconductor device 70 of the modification 6 has a stacked structure (for example, a three-layer structure) in which a chip-shaped second semiconductor structure 200 is bonded to the front surface and the back surface of a chip-shaped first semiconductor structure 100. An example of a method of manufacturing the semiconductor device 70 of the modification 6 will be briefly described. First, a wafer-sized first semiconductor structure 100 (intermediate layer) is bonded to the surface of a wafer-sized second semiconductor structure 200 (lower layer), and then a plurality of chip-shaped second semiconductor structures 200 (upper layer) is bonded to the surface of the first semiconductor structure 100. After the bonding, the positional shift of the connection terminal pair CTp is inspected using the inspection electrode pair Ep, and after the inspection is passed, the three-layer structure is separated into chips.

As illustrated in FIG. 46C, a semiconductor device 80 of the modification 7 has a stacked structure (for example, a three-layer structure) in which a chip-shaped second semiconductor structure 200 is bonded to the front surface and the back surface of a chip-shaped first semiconductor structure 100. An example of a method of manufacturing the semiconductor device 80 of the modification 7 will be briefly described. First, the chip-shaped first semiconductor structure 100 (intermediate layer) is bonded to the surface of the wafer-sized second semiconductor structure 200 (lower layer). After the bonding, the positional shift of the connection terminal pair CTp is inspected using the inspection electrode pair Ep, and after the inspection is passed, the chip-shaped second semiconductor structure 200 is bonded to the surface of each chip-shaped first semiconductor structure 100. After the bonding, the positional shift of the connection terminal pair CTp is inspected using the inspection electrode pair Ep, and after the inspection is passed, the three-layer structure is separated into chips.

### (Semiconductor Devices of Modifications 8 and 9 of Present Technology)

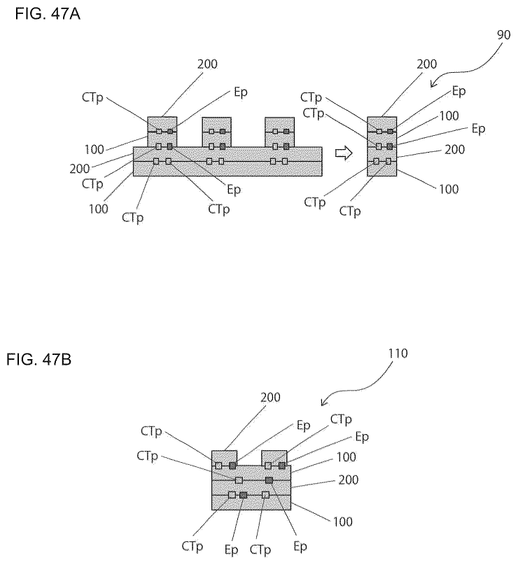

FIGS. 47A and 47B are views respectively schematically illustrating cross-sectional configurations of the semiconductor devices according to modifications 8 and 9 of the present technology.

As illustrated in FIG. 47A, a semiconductor device 90 of the modification 8 has a stacked structure (for example, a four-layer structure) in which a chip-shaped first semiconductor structure 100 and a chip-shaped second semiconductor structure 200 are alternately stacked. An example of a method of manufacturing the semiconductor device 90 of the modification 8 will be briefly described. First, a wafer-sized second semiconductor structure 200 is bonded to the surface of a wafer-sized first semiconductor structure 100 (lowermost layer), and a plurality of chip-shaped first semiconductor structures 100 is bonded to the surface of the second semiconductor structure 200. After the bonding, the positional shift of the connection terminal pair CTp is inspected using the inspection electrode pair Ep, and after the inspection is passed, the chip-shaped second semiconductor structure 200 is bonded to the surface of each chip-shaped first semiconductor structure 100. After the bonding, the positional shift of the connection terminal pair CTp is inspected using the inspection electrode pair Ep, and after the inspection is passed, the four-layer structure is separated into chips.

As illustrated in FIG. 47B, a semiconductor device 110 of the modification 9 has a stacked structure (four-layer structure) in which a wafer-sized first semiconductor structure 100 is bonded to the front surface and the second wiring layers 102 and 202ack surface of semiconductor device wafer-sized second semiconductor device 200, and a plurality of chip-shaped second semiconductor structures 200 (uppermost layer) is bonded to the front surface of the first semiconductor structure 100 on a front surface side of the second semiconductor structure 200. An example of a method of manufacturing the semiconductor device 110 of the modification 9 will be briefly described. First, the wafer-sized second semiconductor structure 200 is bonded to the surface of the wafer-sized first semiconductor structure 100 (lowermost layer). After the bonding, the positional shift of the connection terminal pair CTp is inspected using the inspection electrode pair Ep, and after the inspection is passed, the wafer-sized first semiconductor structure 100 is bonded to the surface of the second semiconductor structure 200. After the bonding, the positional shift of the connection terminal pair CTp is inspected using the inspection electrode pair Ep, and after the inspection is passed, a plurality of chip-shaped second semiconductor structures 200 is bonded to the surface of the first semiconductor structure 100. After the bonding, the positional shift of the connection terminal pair CTp is inspected using the inspection electrode pair Ep, and when the inspection is passed, a passed product is obtained.

### Effects of Semiconductor Device of Present Technology

According to the semiconductor device of the present technology described above, it is not necessary to physically measure the positional shift of the first and second connection terminals. Moreover, since it is not necessary to increase the sizes of the first and second connection terminals, the chip size can be reduced. Thus, the semiconductor device can be provided at low cost.

### 3. Other Modifications of Present Technology

The configurations of the semiconductor devices of the embodiment and each modification described above can be appropriately changed. For example, the above-described configurations of the semiconductor devices of the configuration examples 1 and 2, the example 1, and each of the modifications may be combined with one another within a range not technically contradictory.

### 4. Use Examples of Electronic Device Including Semiconductor Device According to Embodiment of Present Technology

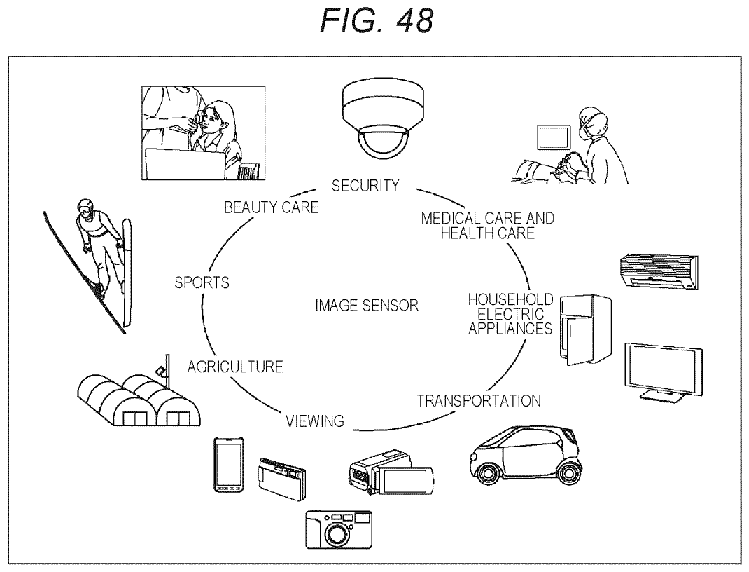

FIG. 48 is a diagram illustrating use examples of an electronic device including the semiconductor device according to the embodiment of the present technology.

The electronic device can be used, for example, in various cases of sensing light such as visible light, infrared light, ultraviolet light, and X-rays as described below. That is, as illustrated in FIG. 48, electronic device can also be used, for example, for devices used in the field of viewing in which images for viewing are captured, the field of transportation, the field of household electric appliances, the field of medical care and healthcare, the field of security, the field of beauty care, the field of sports, the field of agriculture, and the like.

Specifically, in the field of viewing, the electronic device can be used for, for example, a digital camera or a smartphone.

In the field of transportation, for example, for safe driving such as automatic stop, recognition of a state of a driver, and the like, the electronic device can be used for devices used for transportation, such as vehicle-mounted sensors that capture an image in front, rear, surroundings, interior, and the like of an automobile, monitoring cameras that monitor traveling vehicles and roads, and distance measurement sensors that measure a distance between vehicles.

In the field of household electric appliances, for example, in order to capture an image of a user's gesture and operate a device in accordance with the gesture, the electronic device can be used for devices used in household electric appliances such as TV receivers, refrigerators, and air conditioners.

In the field of medical care and healthcare, for example, the electronic device can be used for devices used for medical care and healthcare, such as endoscopes and devices that perform angiography by receiving infrared light.

In the field of security, for example, the electronic device can be used for devices used for security, such as monitoring cameras for crime prevention or cameras for person authentication.

In the field of beauty care, for example, the electronic device can be used for devices used for beauty care, such as skin measuring instruments for image capturing of skin or microscopes for image capturing of scalp.

In the field of sports, for example, the electronic device can be used for devices used for sports such as action cameras and wearable cameras for sports applications and the like.

In the field of agriculture, for example, the electronic device can be used for devices used for agriculture such as cameras for monitoring a condition of fields and crops.

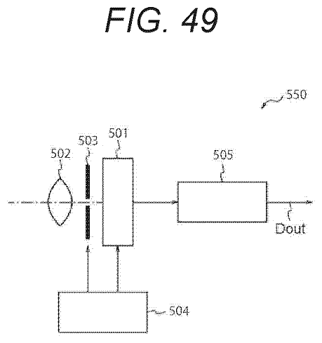

Next, use examples of the electronic device will be specifically described. For example, the electronic device can be applied to any type of electronic device having an imaging function, such as a camera system of a digital still camera or a video camera, or a mobile phone having an imaging function, as an electronic device including the semiconductor device according to each example or including the solid-state imaging device 501 including the semiconductor device. FIG. 49 illustrates a schematic configuration of an electronic device 550 (camera) as an example. The electronic device 550 is, for example, a video camera capable of capturing a still image or a moving image, and includes the solid-state imaging device 501, an optical system (optical lens) 502, a shutter device 503, a drive unit 504 that drives the solid-state imaging device 501 and the shutter device 503, and a signal processing unit 505.

The optical system 502 guides image light (incident light) from an object to a pixel region of the solid-state imaging device 501. The optical system 502 may include a plurality of optical lenses. The shutter device 503 controls a light irradiation period and a light shielding period regarding the solid-state imaging device 501. The drive unit 504 controls a transfer operation of the solid-state imaging device 501 and a shutter operation of the shutter device 503. The signal processing unit 505 performs various types of signal processing on a signal output from the solid-state imaging device 501. A video signal Dout after the signal processing is stored in a storage medium such as a memory or output to a monitor and the like.

### 5. Other Use Examples of Electronic Device Including Semiconductor Device According to Embodiment of Present Technology

The electronic device including the semiconductor device according to the embodiment of the present technology can also be applied to other electronic devices that detect light, such as a time of flight (TOF) sensor, for example. In a case of applying the electronic device to a TOF sensor, for example, the electronic device can be applied to a distance image sensor by a direct TOF measurement method and a distance image sensor by an indirect TOF measurement method. In the distance image sensor by the direct TOF measurement method, arrival timing of photons is directly obtained in a time domain in each pixel. Therefore, a light pulse having a short pulse width is transmitted, and an electrical pulse is generated by a receiver that responds at a high speed. The present disclosure can be applied to the receiver at that time. Furthermore, in the indirect TOF method, a flight time of light is measured using a semiconductor element structure in which detection and an accumulation amount of carriers generated by light change depending on the arrival timing of light. The present disclosure can also be applied to such a semiconductor structure. In the case of application to a TOF sensor, it is arbitrary to provide a color filter array and a microlens array, and the color filter array and microlens array may not be provided.

### 6. Application Examples to Mobile Objects

The technology according to the present disclosure (present technology) can be applied to various products. For example, the technology according to the present disclosure may be implemented as a device mounted on any type of mobile objects, such as an automobile, an electric vehicle, a hybrid electric vehicle, a motorcycle, a bicycle, personal mobility, an airplane, a drone, a ship, a robot, and the like.

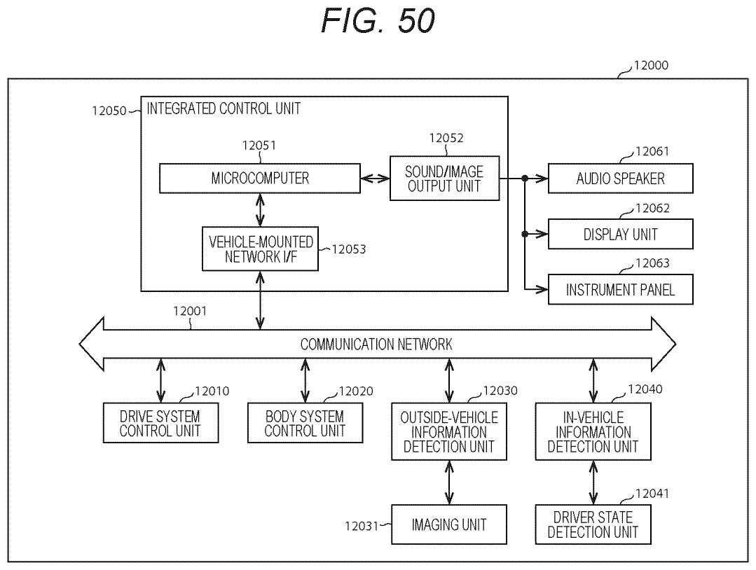

FIG. 50 is a block diagram illustrating a schematic configuration example of a vehicle control system that is an example of a mobile body control system to which the technology according to the present disclosure is applicable.

The vehicle control system 12000 includes a plurality of electronic control units connected to each other via a communication network 12001. In the example illustrated in FIG. 50, the vehicle control system 12000 includes a drive system control unit 12010, a body system control unit 12020, an outside-vehicle information detection unit 12030, an in-vehicle information detection unit 12040, and an integrated control unit 12050. Furthermore, a microcomputer 12051, a sound/image output unit 12052, and a vehicle-mounted network interface (I/F) 12053 are illustrated as a functional configuration of the integrated control unit 12050.

The drive system control unit 12010 controls the operation of devices related to the drive system of the vehicle in accordance with various kinds of programs. For example, the drive system control unit 12010 functions as a control device for a driving force generating device for generating a driving force of the vehicle, such as an internal combustion engine or a drive motor, a driving force transmitting mechanism for transmitting the driving force to wheels, a steering mechanism for adjusting a steering angle of the vehicle, a braking device for generating a braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detection unit 12030 detects information about the outside of the vehicle including the vehicle control system 12000. For example, the outside-vehicle information detection unit 12030 is connected with an imaging unit 12031. The outside-vehicle information detection unit 12030 causes the imaging unit 12031 to capture an image of the outside of the vehicle, and receives the captured image. On the basis of the received image, the outside-vehicle information detection unit 12030 may perform processing of detecting an object such as a human, a vehicle, an obstacle, a sign, a character on a road surface, or the like, or processing of detecting a distance thereto.

The imaging unit 12031 is an optical sensor that receives light, and which outputs an electric signal corresponding to a received light amount of the light. The imaging unit 12031 can output the electric signal as an image, or can output the electric signal as information about a measured distance. Furthermore, the light received by the imaging unit 12031 may be visible light, or may be invisible light such as infrared rays or the like.

The in-vehicle information detection unit 12040 detects information about the inside of the vehicle. The in-vehicle information detection unit 12040 is, for example, connected with a driver state detection unit 12041 that detects the state of a driver. The driver state detection unit 12041, for example, includes a camera that captures an image of the driver. On the basis of detection information input from the driver state detection unit 12041, the in-vehicle information detection unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information of the inside or outside of the vehicle obtained by the outside-vehicle information detection unit 12030 or the in-vehicle information detection unit 12040, and output a control command to the drive system control unit 12010. For example, the microcomputer 12051 can perform cooperative control intended to implement functions of an advanced driver assistance system (ADAS) that functions include collision avoidance or shock mitigation for the vehicle, following driving based on a following distance, vehicle speed maintaining driving, a warning of collision of the vehicle, a warning of shift of the vehicle from a lane, or the like.

Furthermore, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information of the outside or inside of the vehicle obtained by the outside-vehicle information detection unit 12030 or the in-vehicle information detection unit 12040.

Furthermore, the microcomputer 12051 can output a control command to the body system control unit 12020 on the basis of the information about the outside of the vehicle, which is obtained by the outside-vehicle information detection unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detection unit 12030.

The sound/image output unit 12052 transmits an output signal of at least one of a sound and an image to an output device capable of visually or auditorily notifying information to an occupant of the vehicle or the outside of the vehicle. In the example of FIG. 50, an audio speaker 12061, a display unit 12062, and an instrument panel 12063 are illustrated as the output device. The display unit 12062 may, for example, include at least one of an on-board display and a head-up display.

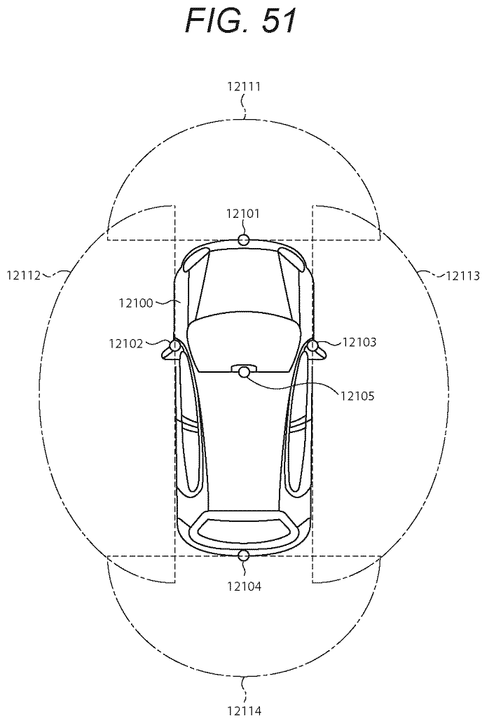

FIG. 51 illustrates an example of installation positions of the imaging units 12031.

In FIG. 51, a vehicle 12100 includes imaging units 12101, 12102, 12103, 12104, and 12105, as the imaging unit 12031.

The imaging units 12101, 12102, 12103, 12104, and 12105 are, for example, provided at positions on a front nose, sideview mirrors, a rear bumper, and a back door of the vehicle 12100 as well as a position on an upper portion of a windshield in the interior of the vehicle. The imaging unit 12101 provided to the front nose and the imaging unit 12105 provided to the upper portion of the windshield within the interior of the vehicle obtain mainly an image of the front of the vehicle 12100. The imaging units 12102 and 12103 provided to the sideview mirrors mainly obtain images of the sides of the vehicle 12100. The imaging unit 12104 provided to the rear bumper or the back door obtains mainly an image of the rear of the vehicle 12100. The forward images obtained by the imaging units 12101 and 12105 are used mainly to detect a preceding vehicle, a pedestrian, an obstacle, a traffic signal, a traffic sign, a lane, or the like.

Note that FIG. 51 illustrates an example of imaging ranges of the imaging units 12101 to 12104. An imaging range 12111 represents the imaging range of the imaging unit 12101 provided to the front nose. Imaging ranges 12112 and 12113 respectively represent the imaging ranges of the imaging units 12102 and 12103 provided to the sideview mirrors. An imaging range 12114 represents the imaging range of the imaging unit 12104 provided to the rear bumper or the back door. A bird's-eye image of the vehicle 12100 as viewed from above is obtained by superimposing image data captured by the imaging units 12101 to 12104, for example.

At least one of the imaging units 12101 to 12104 may have a function of obtaining distance information. For example, at least one of the imaging units 12101 to 12104 may be a stereo camera including a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging units 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging units 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display unit 12062, and performs forced deceleration or avoidance steering via the drive system control unit 12010. The microcomputer 12051 can thereby assist in driving to avoid collision.

At least one of the imaging units 12101 to 12104 may be an infrared camera that detects infrared rays. The microcomputer 12051 can, for example, recognize a pedestrian by determining whether or not there is a pedestrian in captured images of the imaging units 12101 to 12104. Such recognition of a pedestrian is, for example, performed by a procedure of extracting characteristic points in the captured images of the imaging units 12101 to 12104 as infrared cameras and a procedure of determining whether or not it is the pedestrian by performing pattern matching processing on a series of characteristic points representing the contour of the object. When the microcomputer 12051 determines that there is a pedestrian in the captured images of the imaging units 12101 to 12104, and thus recognizes the pedestrian, the sound/image output unit 12052 controls the display unit 12062 so that a square contour line for emphasis is displayed so as to be superimposed on the recognized pedestrian. Furthermore, the sound/image output unit 12052 may also control the display unit 12062 so that an icon or the like representing the pedestrian is displayed at a desired position.

An example of the vehicle control system to which the technology according to the present disclosure (present technology) can be applied has been described above. The technology according to the present disclosure can be applied to the imaging unit 12031 and the like, for example, out of the configurations described above. Specifically, for example, the solid-state imaging device 111 of the present disclosure can be applied to the imaging unit 12031. By applying the technology according to the present disclosure to the imaging unit 12031, it is possible to improve yield and reduce cost related to manufacturing.

### 7. Application Example to Endoscopic Surgery System

The present technology is applicable to various products. For example, the technology according to the present disclosure (present technology) may be applied to an endoscopic surgery system.

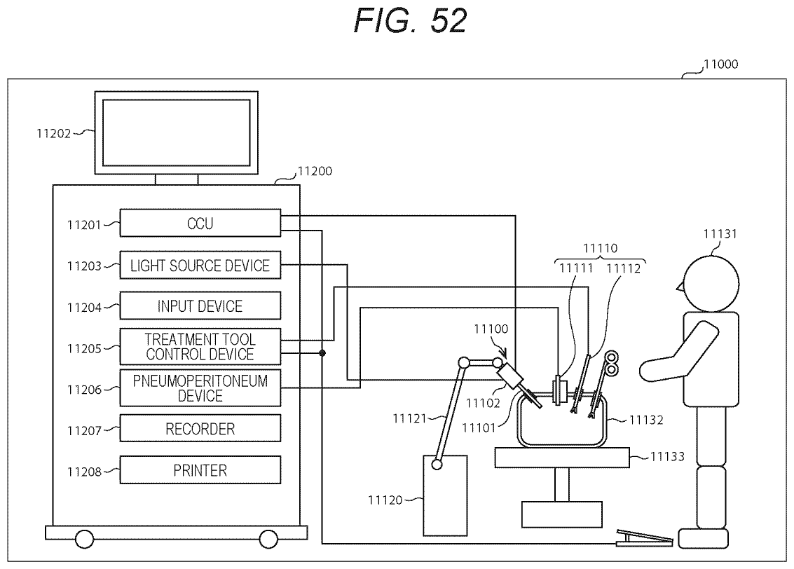

FIG. 52 is a view illustrating an example of a schematic configuration of an endoscopic surgery system to which the technology according to the present disclosure (present technology) can be applied.

FIG. 52 illustrates a state in which a surgeon (medical doctor) 11131 is using an endoscopic surgery system 11000 to perform surgery for a patient 11132 on a patient bed 11133. As illustrated, the endoscopic surgery system 11000 includes an endoscope 11100, other surgical tools 11110 such as a pneumoperitoneum tube 11111 and an energy treatment tool 11112, a supporting arm device 11120 that supports the endoscope 11100, and a cart 11200 on which various devices for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example illustrated, the endoscope 11100 is illustrated that includes as a rigid endoscope having the lens barrel 11101 of the hard type. However, the endoscope 11100 may otherwise be included as a flexible endoscope having the lens barrel of the flexible type.

The lens barrel 11101 has, at a distal end thereof, an opening in which an objective lens is fitted. A light source device 11203 is connected to the endoscope 11100 such that light generated by the light source device 11203 is introduced to a distal end of the lens barrel 11101 by a light guide extending in the inside of the lens barrel 11101 and is irradiated toward an observation target in a body cavity of the patient 11132 through the objective lens. Note that the endoscope 11100 may be a forward-viewing endoscope or may be an oblique-viewing endoscope or a side-viewing endoscope.

An optical system and an imaging element are provided in the inside of the camera head 11102 such that reflected light (observation light) from the observation target is condensed on the imaging element by the optical system. The observation light is photo-electrically converted by the imaging element to generate an electric signal corresponding to the observation light, namely, an image signal corresponding to an observation image. The image signal is transmitted as raw data to a camera control unit (CCU) 11201.

The CCU 11201 includes a central processing unit (CPU), a graphics processing unit (GPU) or the like and integrally controls operation of the endoscope 11100 and a display device 11202. Moreover, the CCU 11201 receives an image signal from the camera head 11102 and performs, for the image signal, various image processes for displaying an image based on the image signal such as, for example, a development process (demosaic process).

The display device 11202 displays thereon an image based on an image signal, for which the image processes have been performed by the CCU 11201, under the control of the CCU 11201.

The light source device 11203 includes a light source such as, for example, a light emitting diode (LED) and supplies irradiation light when capturing an image of a surgical region to the endoscope 11100.

An inputting device 11204 is an input interface for the endoscopic surgery system 11000. A user can perform inputting of various kinds of information or instruction inputting to the endoscopic surgery system 11000 through the inputting device 11204. For example, the user inputs an instruction or a like to change an imaging condition (type of irradiation light, magnification, focal distance or the like) by the endoscope 11100.

A treatment tool controlling device 11205 controls driving of the energy treatment tool 11112 for cautery or incision of a tissue, sealing of a blood vessel or the like. A pneumoperitoneum device 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is a device capable of recording various kinds of information relating to surgery. A printer 11208 is a device capable of printing various kinds of information relating to surgery in various forms such as a text, an image or a graph.

Note that the light source device 11203 that supplies irradiation light when a surgical region is to be captured to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source device 11203. Furthermore, in this case, it is also possible to capture an image corresponding to each of RGB in a time division manner by irradiating the observation target with laser light from each of the RGB laser light sources in a time-division manner, and controlling driving of the imaging element of the camera head 11102 in synchronization with the irradiation timing. With this method, a color image can be obtained even if color filters are not provided to the imaging element.

Furthermore, the light source device 11203 may be controlled such that the intensity of light to be outputted is changed for each predetermined time. By controlling driving of the imaging element of the camera head 11102 in synchronism with the timing of the change of the intensity of light to acquire images time-divisionally and synthesizing the images, an image of a high dynamic range free from underexposed blocked up shadows and overexposed highlights can be created.

Furthermore, the light source device 11203 may be configured to supply light of a predetermined wavelength band ready for special light observation. In special light observation, for example, by utilizing the wavelength dependency of absorption of light in a body tissue to irradiate light of a narrow band in comparison with irradiation light at ordinary observation (namely, white light), narrow band observation (narrow band imaging) of capturing an image of a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source device 11203 can be configured to supply such narrow-band light and/or excitation light suitable for special light observation as described above.

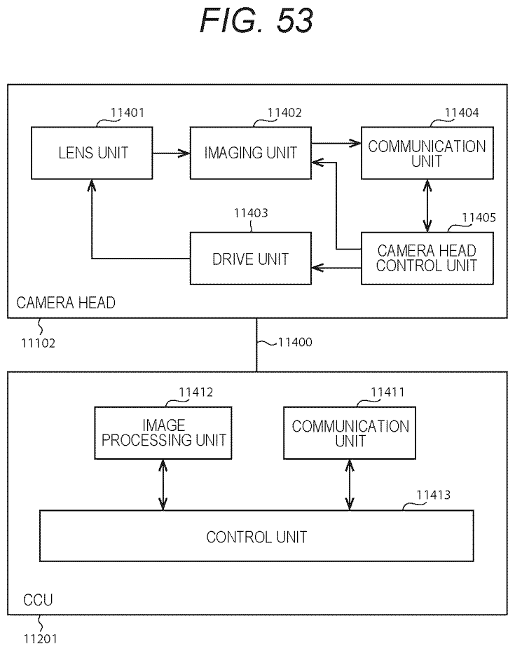

FIG. 53 is a block diagram illustrating an example of a functional configuration of the camera head 11102 and the CCU 11201 illustrated in FIG. 52.

The camera head 11102 includes a lens unit 11401, an imaging unit 11402, a drive unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The imaging unit 11402 includes an imaging element. The number of imaging elements that constitutes the imaging unit 11402 may be one (single-plate type) or a plural number (multi-plate type). Where the imaging unit 11402 is configured as that of the multi-plate type, for example, image signals corresponding to respective R, G and B are generated by the imaging elements, and the image signals may be synthesized to obtain a color image. Alternatively, the imaging unit 11402 may include a pair of imaging elements for acquiring right-eye and left-eye image signals corresponding to three-dimensional (3D) display. If 3D display is performed, then the depth of a living body tissue in a surgical region can be comprehended more accurately by the surgeon 11131. Note that, in a case where the imaging unit 11402 is configured as that of multi-plate type, a plurality of systems of lens units 11401 may be provided corresponding to the respective imaging elements.

Furthermore, the imaging unit 11402 may not necessarily be provided on the camera head 11102. For example, the imaging unit 11402 may be provided immediately behind the objective lens in the inside of the lens barrel 11101.

The drive unit 11403 includes an actuator and moves the zoom lens and the focusing lens of the lens unit 11401 by a predetermined distance along an optical axis under the control of the camera head controlling unit 11405. Therefore, the magnification and the focal point of a picked up image by the imaging unit 11402 can be adjusted suitably.

The communication unit 11404 includes a communication device for transmitting and receiving various kinds of information to and from the CCU 11201. The communication unit 11404 transmits an image signal acquired from the imaging unit 11402 as raw data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to imaging conditions such as, for example, information that a frame rate of a picked up image is designated, information that an exposure value upon image picking up is designated and/or information that a magnification and a focal point of a picked up image are designated.

Note that the imaging conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication device for transmitting and receiving various kinds of information to and from the camera head 11102. The communication unit 11411 receives an image signal transmitted thereto from the camera head 11102 through the transmission cable 11400.

Furthermore, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of raw data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Furthermore, the control unit 11413 controls, on the basis of an image signal for which image processes have been performed by the image processing unit 11412, the display device 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display device 11202 to display a picked up image, various kinds of surgery supporting information to be displayed in an overlapping manner with an image of the surgical region using a result of the recognition. In a case where surgery supporting information is displayed in an overlapping manner and presented to the surgeon 11131, the burden on the surgeon 11131 can be reduced and the surgeon 11131 can proceed with the surgery with certainty.

The transmission cable 11400 that connects the camera head 11102 and the CCU 11201 to each other is an electric signal cable ready for communication of an electric signal, an optical fiber ready for optical communication or a composite cable ready for both of electrical and optical communications.

Here, while, in the example illustrated, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to the endoscope 11100, (the imaging unit 11402 of) the camera head 11102, and the like out of the configurations described above. Specifically, the solid-state imaging device 111 of the present disclosure can be applied to the imaging unit 10402. By applying the technology according to the present disclosure to the endoscope 11100, (the imaging unit 11402 of) the camera head 11102, and the like, it is possible to improve yield and reduce cost related to manufacturing.

Here, the endoscopic surgery system has been described as an example, but the technology according to the present disclosure may be applied to other, for example, a microscopic surgery system or the like.

Furthermore, the present technology may also adopt the following configurations.
(1) A semiconductor device having a stacked structure in which a first semiconductor structure and a second semiconductor structure are stacked and bonded, in which
the first semiconductor structure includes a first connection terminal exposed to a first bonding surface that is a bonding surface to the second semiconductor structure,
the second semiconductor structure includes a second connection terminal exposed to a second bonding surface that is a bonding surface to the first semiconductor structure, and bonded to the first connection terminal, and
the stacked structure includes at least one of
a first electrode provided in the first semiconductor structure, and capable of changing an electrical characteristic with respect to the second semiconductor structure according to a positional shift between the first connection terminal and the second connection terminal, or
a second electrode provided in the second semiconductor structure, and capable of changing an electrical characteristic with respect to the first semiconductor structure according to the positional shift.
(2) The semiconductor device according to (1), in which the stacked structure includes the first electrode, and the first electrode is provided in the first semiconductor structure so as to be exposed to the first bonding surface, and a state of the first electrode is variable between a state of being in conduction with the second semiconductor structure and a state of being not in conduction with the second semiconductor structure according to the positional shift.
(3) The semiconductor device according to (1) or (2), in which the first electrode is disposed at a position where a state of the first electrode is changeable between a contact state of being in contact with the second connection terminal and a non-contact state of being not in contact with the second connection terminal according to the positional shift.
(4) The semiconductor device according to (3), in which the state of the first electrode of the first electrode is different between the contact state and the non-contact state between when the positional shift is equal to or less than a predetermined value and when the positional shift exceeds the predetermined value.
(5) The semiconductor device according to (4), in which the first electrode is in the non-contact state when the positional shift is equal to or less than the predetermined value, and is in the contact state when the positional shift exceeds the predetermined value.
(6) The semiconductor device according to (4), in which the first electrode is in the contact state when the positional shift is equal to or less than the predetermined value, and is in the non-contact state when the positional shift exceeds the predetermined value.
(7) The semiconductor device according to (1), in which the stacked structure includes the second electrode, and the second electrode is provided in the second semiconductor structure so as to be exposed to the second bonding surface, and a state of the second electrode is variable between a state of being in conduction with the first semiconductor structure and a state of being not in conduction with the first semiconductor structure according to the positional shift.
(8) The semiconductor device according to (7), in which the second electrode is disposed at a position where a state of the second electrode is changeable between a contact state of being in contact with the first connection terminal and a non-contact state of being not in contact with the first connection terminal according to the positional shift.
(9) The semiconductor device according to (7) or (8), in which the state of the second electrode is different between the contact state and the non-contact state between when the positional shift is equal to or less than a predetermined value and when the positional shift exceeds the predetermined value.
(10) The semiconductor device according to claim 9, in which the second electrode is in the non-contact state when the positional shift is equal to or less than the predetermined value, and is in the contact state when the positional shift exceeds the predetermined value.
(11) The semiconductor device according to (9), in which the second electrode is in the contact state when the positional shift is equal to or less than the predetermined value, and is in the non-contact state when the positional shift exceeds the predetermined value.
(12) The semiconductor device according to (1), in which the stacked structure includes the first electrode and the second electrode.
(13) The semiconductor device according to (12), in which the first electrode and the second electrode are disposed at positions where states of the first electrode and the second electrode are changeable between a contact state of being in contact with each other and a non-contact state of being not in contact with each other according to the positional shift.
(14) The semiconductor device according to (12) or (13), in which the states of the first electrode and the second electrode are different between the contact state and the non-contact state between when the positional shift is equal to or less than a predetermined value and when the positional shift exceeds the predetermined value.
(15) The semiconductor device according to (14), in which the first electrode and the second electrode are in the non-contact state when the positional shift is equal to or less than the predetermined value, and are in the contact state when the positional shift exceeds the predetermined value.
(16) The semiconductor device according to (14), in which the first electrode and the second electrode are in the contact state when the positional shift is equal to or less than the predetermined value, and are in the non-contact state when the positional shift exceeds the predetermined value.
(17) The semiconductor device according to (1), in which the stacked structure includes the first electrode and the second electrode, and the first electrode and the second electrode are arranged at positions where capacitance between the first electrode and the second electrode is changeable according to the positional shift.
(18) The semiconductor device according to any one of (12) to (17), in which the stacked structure includes a detection system that electrically detects a positional relationship between the first electrode and the second electrode to detect a magnitude and/or a direction of the positional shift.
(19) The semiconductor device according to any one of (12) to (18), in which the stacked structure includes a determination system that is provided in at least one of the first semiconductor structure or the second semiconductor structure, and determines a change in the electrical characteristic between the first electrode and the second electrode.
(20) The semiconductor device according to any one of (1) to (19), in which the first semiconductor structure and the second semiconductor structure have different sizes.
(21) The semiconductor device according to any one of (1) to (20), in which one of the first semiconductor structure and the second semiconductor structure includes a pixel unit having a photoelectric conversion element, and the other of the first semiconductor structure and the second semiconductor structure processes a signal output from the pixel unit.

### REFERENCE SIGNS LIST

1, 2, 10, 20, 30, 40, 50, 60, 70, 80, 90, 110 Semiconductor device
100, SS1 First semiconductor structure
102e1, 102e, CT1 First connection terminal
102e2, E1 First electrode
202e, 202e1 Second connection terminal
202e2, E2 Second electrode
200, SS2 Second semiconductor structure

1. A semiconductor device having a stacked structure in which a first semiconductor structure and a second semiconductor structure are stacked and bonded, wherein
the first semiconductor structure includes a first connection terminal exposed to a first bonding surface that is a bonding surface to the second semiconductor structure,
the second semiconductor structure includes a second connection terminal exposed to a second bonding surface that is a bonding surface to the first semiconductor structure, and bonded to the first connection terminal, and
the stacked structure includes at least one of
a first electrode provided in the first semiconductor structure, and capable of changing an electrical characteristic with respect to the second semiconductor structure according to a positional shift between the first connection terminal and the second connection terminal, or
a second electrode provided in the second semiconductor structure, and capable of changing an electrical characteristic with respect to the first semiconductor structure according to the positional shift.

2. The semiconductor device according to claim 1, wherein
the stacked structure includes the first electrode, and
the first electrode is provided in the first semiconductor structure so as to be exposed to the first bonding surface, and a state of the first electrode is variable between a state of being in conduction with the second semiconductor structure and a state of being not in conduction with the second semiconductor structure according to the positional shift.

3. The semiconductor device according to claim 2, wherein the first electrode is disposed at a position where a state of the first electrode is changeable between a contact state of being in contact with the second connection terminal and a non-contact state of being not in contact with the second connection terminal according to the positional shift.

4. The semiconductor device according to claim 3, wherein the state of the first electrode is different between the contact state and the non-contact state between when the positional shift is equal to or less than a predetermined value and when the positional shift exceeds the predetermined value.

5. The semiconductor device according to claim 4, wherein the first electrode is in the non-contact state when the positional shift is equal to or less than the predetermined value, and is in the contact state when the positional shift exceeds the predetermined value.

6. The semiconductor device according to claim 4, wherein the first electrode is in the contact state when the positional shift is equal to or less than the predetermined value, and is in the non-contact state when the positional shift exceeds the predetermined value.

7. The semiconductor device according to claim 1, wherein
the stacked structure includes the second electrode, and
the second electrode is provided in the second semiconductor structure so as to be exposed to the second bonding surface, and a state of the second electrode is variable between a state of being in conduction with the first semiconductor structure and a state of being not in conduction with the first semiconductor structure according to the positional shift.

8. The semiconductor device according to claim 7, wherein the second electrode is disposed at a position where a state of the second electrode is changeable between a contact state of being in contact with the first connection terminal and a non-contact state of being not in contact with the first connection terminal according to the positional shift.

9. The semiconductor device according to claim 8, wherein the state of the second electrode is different between the contact state and the non-contact state between when the positional shift is equal to or less than a predetermined value and when the positional shift exceeds the predetermined value.

10. The semiconductor device according to claim 9, wherein the second electrode is in the non-contact state when the positional shift is equal to or less than the predetermined value, and is in the contact state when the positional shift exceeds the predetermined value.

11. The semiconductor device according to claim 9, wherein the second electrode is in the contact state when the positional shift is equal to or less than the predetermined value, and is in the non-contact state when the positional shift exceeds the predetermined value.

12. The semiconductor device according to claim 1, wherein the stacked structure includes the first electrode and the second electrode.

13. The semiconductor device according to claim 12, wherein the first electrode and the second electrode are disposed at positions where states of the first electrode and the second electrode are changeable between a contact state of being in contact with each other and a non-contact state of being not in contact with each other according to the positional shift.

14. The semiconductor device according to claim 13, wherein the states of the first electrode and the second electrode are different between the contact state and the non-contact state between when the positional shift is equal to or less than a predetermined value and when the positional shift exceeds the predetermined value.

15. The semiconductor device according to claim 14, wherein the first electrode and the second electrode are in the non-contact state when the positional shift is equal to or less than the predetermined value, and are in the contact state when the positional shift exceeds the predetermined value.

16. The semiconductor device according to claim 14, wherein the first electrode and the second electrode are in the contact state when the positional shift is equal to or less than the predetermined value, and are in the non-contact state when the positional shift exceeds the predetermined value.

17. The semiconductor device according to claim 1, wherein
the stacked structure includes the first electrode and the second electrode, and
the first electrode and the second electrode are arranged at positions where capacitance between the first electrode and the second electrode is changeable according to the positional shift.

18. The semiconductor device according to claim 12, wherein the stacked structure includes a detection system that electrically detects a positional relationship between the first electrode and the second electrode to detect a magnitude and/or a direction of the positional shift.

19. The semiconductor device according to claim 12, wherein the stacked structure includes a determination system that is provided in at least one of the first semiconductor structure or the second semiconductor structure, and determines a change in the electrical characteristic between the first electrode and the second electrode.

20. The semiconductor device according to claim 1, wherein the first semiconductor structure and the second semiconductor structure have different sizes.
